(19) United States
(12) Patent Application Publication
(10) Pub. No.: US 2025/0293197 A1
(43) Pub. Date: Sep. 18, 2025

(54) PACKAGE COMPRISING INTEGRATED DEVICES AND WIRE BONDS COUPLED TO INTEGRATED DEVICES

(71) Applicant: QUALCOMM Incorporated, San Diego, CA (US)

(72) Inventors: Aniket PATIL, San Diego, CA (US); Joan Rey Villarba BUOT, Escondido, CA (US); Zhijie WANG, San Diego, CA (US)

(21) Appl. No.: 18/605,524

(22) Filed: Mar. 14, 2024

(51) Int. Cl. H01L 23/00; H01L 23/373; H01L 23/538; H01L 25/065

(52) U.S. Cl. CPC H01L 24/48; H01L 23/3738; H01L 23/538; H01L 24/13; H01L 24/16; H01L 24/73; H01L 25/0655; H01L 2224/1357; H01L 2224/16227; H01L 2224/4814; H01L 2224/48465; H01L 2224/48471; H01L 2224/73257; H01L 2924/1437

(57) ABSTRACT

A package comprising a substrate; a first integrated device coupled to the substrate; a second integrated device coupled to the substrate; and a plurality of wire bonds coupled to the first integrated device and the second integrated device.

### FIELD

Various features relate to packages with substrates and integrated devices.

### BACKGROUND

A package may include a substrate and integrated devices. These components are coupled together to provide a package that may perform various electrical functions. There is an ongoing need to provide better performing packages. Moreover, there is also an ongoing need to reduce the overall size of the packages.

### SUMMARY

Various features relate to packages with substrates and integrated devices.

One example provides a package comprising a substrate; a first integrated device coupled to the substrate; a second integrated device coupled to the substrate; and a plurality of wire bonds coupled to the first integrated device and the second integrated device.

Another example provides a package comprising a substrate; a first integrated device coupled to the substrate; a second integrated device coupled to the substrate; and a flexible cable coupled to the first integrated device and the second integrated device.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes a substrate, integrated devices and wire bonds.

FIG. 2 illustrates an exemplary view of wire bonds between two integrated devices.

FIG. 3 illustrates an exemplary view of a wire bond between two integrated devices.

FIG. 4 illustrates an exemplary view of another wire bond between two integrated devices.

FIG. 5 illustrates an exemplary view of an integrated device.

FIG. 6 illustrates an exemplary cross sectional profile view of a package that includes a substrate, integrated devices and wire bonds.

FIG. 7 illustrates an exemplary view of wire bonds between two integrated devices.

FIG. 8 illustrates an exemplary cross sectional profile view of a package that includes a substrate, integrated devices and wire bonds.

FIG. 9 illustrates an exemplary cross sectional profile view of a package that includes a substrate, integrated devices and wire bonds.

FIG. 10 illustrates an exemplary cross sectional profile view of a package that includes a substrate, integrated devices and wire bonds.

FIG. 11 illustrates an exemplary cross sectional profile view of a package that includes a substrate, integrated devices and a flexible cable.

FIG. 12 illustrates an exemplary plan view of a flexible cable.

FIG. 13 illustrates an exemplary cross section view of a flexible cable.

FIG. 14 illustrates an exemplary cross section view of a flexible cable.

FIG. 15 illustrates an exemplary cross sectional profile view of a package that includes a substrate, integrated devices and a flexible cable.

FIG. 16 illustrates an exemplary cross sectional profile view of a package that includes a substrate, integrated devices and a flexible cable.

FIG. 17 illustrates an exemplary cross sectional profile view of a package that includes a substrate, integrated devices and wire bonds.

FIGS. 18A-18C illustrate an exemplary sequence for fabricating a package that includes a substrate, integrated devices and wire bonds.

FIG. 19 illustrates an exemplary flow chart of a method for fabricating a package that includes a substrate, integrated devices and wire bonds.

FIGS. 20A-20B illustrate an exemplary sequence for fabricating a substrate.

FIG. 21 illustrates an exemplary flow chart of a method for fabricating a substrate.

FIG. 22 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure a package comprising a substrate; a first integrated device coupled to the substrate; a second integrated device coupled to the substrate; and a plurality of wire bonds coupled to the first integrated device and the second integrated device. In some implementations, instead of a plurality of wire bonds, a flexible cable may be used that is coupled to the first integrated device and the second integrated device. The use of the plurality of wire bonds and/or the flexible cable may help improve the performance of the package and/or reduce the overall form factor of the package.

### Exemplary Packages Comprising a Substrate, Integrated Devices and Wire Bonds

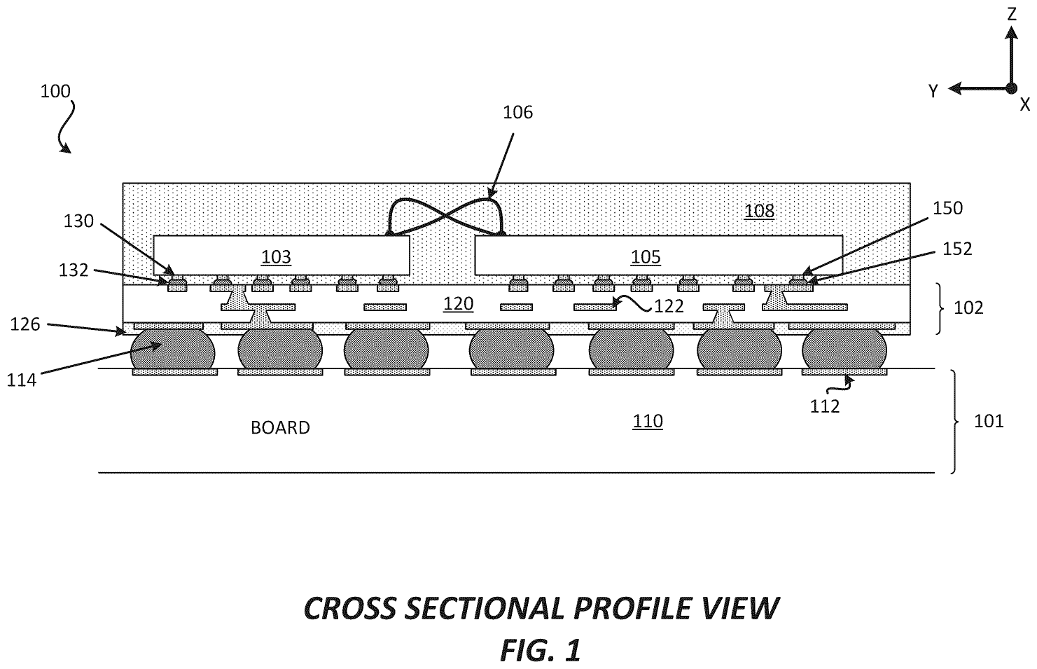

FIG. 1 illustrates a cross sectional profile view of a package 100 that includes wire bonds between integrated devices. The package 100 may be implemented as part of a package on package (PoP). The package 100 is coupled to a board 101 through a plurality of solder interconnects 114. The board 101 includes at least one board dielectric layer 110 and a plurality of board interconnects 112. The board 101 may include a printed circuit board (PCB).

The package 100 includes a substrate 102, an integrated device 103, an integrated device 105, a plurality of wire bonds 106 and an encapsulation layer 108. The substrate 102 includes a dielectric layer 120, a plurality of interconnects 122 and a solder resist layer 126. The substrate 102 is coupled to the board 101 through the plurality of solder interconnects 114. The integrated device 103 is coupled to the substrate 102 through at least a plurality of solder interconnects 132. For example, the integrated device 103 is coupled to a plurality of interconnects 122 of the substrate 102 through a plurality of pillar interconnects 130 and/or a plurality of solder interconnects 132. The integrated device 105 is coupled to the substrate 102 through at least a plurality of solder interconnects 152. For example, the integrated device 105 is coupled to a plurality of interconnects 122 of the substrate 102 through a plurality of pillar interconnects 150 and/or a plurality of solder interconnects 152.

The plurality of wire bonds 106 are coupled to the integrated device 103 (e.g., first integrated device) and the integrated device 105 (e.g., second integrated device). For example, the plurality of wire bonds 106 may be coupled to a back side of the integrated device 103 and a back side of the integrated device 105. The plurality of wire bonds 106 may be configured to provide electrical paths between the integrated device 103 and the integrated device 105. The plurality of wire bonds 106 may include copper (Cu) and/or gold (Au). However, different implementations may use different metals and/or electrically conductive materials for the plurality of wire bonds 106.

The encapsulation layer 108 is coupled to the substrate 102. The encapsulation layer 108 may at least partially encapsulate the integrated device 103, the integrated device 105 and the plurality of wire bonds 106. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

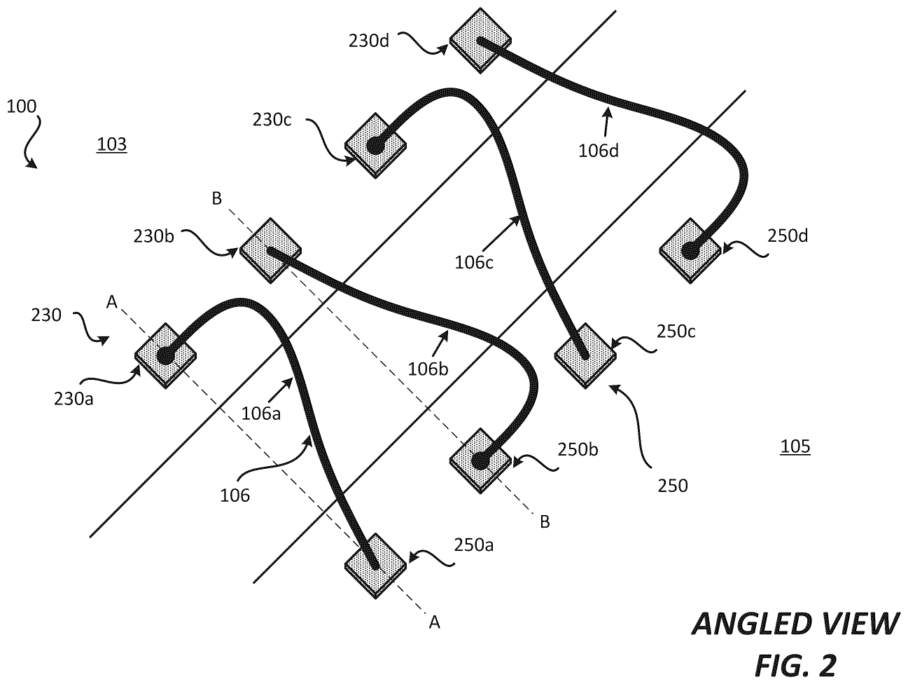

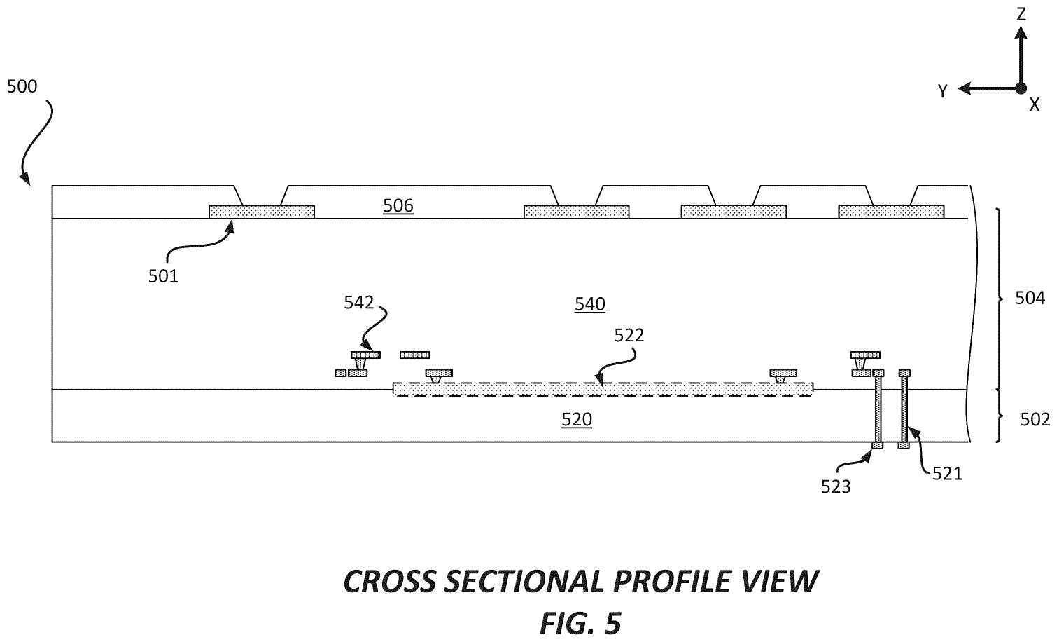

FIG. 2 illustrates a close up view of the plurality of wire bonds 106 that are coupled to the integrated device 103 and the integrated device 105 of the package 100. As shown in FIG. 2, the integrated device 103 includes a plurality of pad interconnects 230, and the integrated device 105 includes a plurality of pad interconnects 250. The plurality of pad interconnects 230 may be located on the back side of the integrated device 103. The plurality of pad interconnects 230 may be part of a back side metallization portion of the integrated device 103. The plurality of pad interconnects 230 may be coupled to through substrate vias of the integrated device 103. The plurality of pad interconnects 250 may be located on the back side of the integrated device 105. The plurality of pad interconnects 250 may be part of a back side metallization portion of the integrated device 105. The plurality of pad interconnects 250 may be coupled to through substrate vias of the integrated device 105. A more detailed example of an exemplary integrated device with through substrate vias and a back side metallization portion is further illustrated and described below in at least FIG. 5.

The plurality of pad interconnects 230 includes a pad interconnect 230a, a pad interconnect 230b, a pad interconnect 230c and a pad interconnect 230d. The plurality of pad interconnects 230 are located in a row along an edge of the integrated device 103. The plurality of pad interconnects 250 includes a pad interconnect 250a, a pad interconnect 250b, a pad interconnect 250c and a pad interconnect 250d. The plurality of pad interconnects 250 are located in a row along an edge of the integrated device 105. The plurality of wire bonds 106 includes a wire bond 106a, a wire bond 106b, a wire bond 106c and a wire bond 106d. The plurality of wire bonds 106 are coupled to (i) the plurality of pad interconnects 230 of the integrated device 103 and (ii) the plurality of pad interconnects 250 of the integrated device 105.

The wire bond 106a may be coupled to (i) the pad interconnect 230a, and (ii) the pad interconnect 250a. The wire bond 106b may be coupled to (i) the pad interconnect 230b, and (ii) the pad interconnect 250b. The wire bond 106c may be coupled to (i) the pad interconnect 230c, and (ii) the pad interconnect 250c. The wire bond 106d may be coupled to (i) the pad interconnect 230d, and (ii) the pad interconnect 250d.

FIG. 2 illustrates that the wire bonds from the plurality of wire bonds 106 may be oriented in different alignments, directions and/or configurations. In one example, the wire bonds may alternate back in forth and worth in different alignments. For example, the wire bond 106a and the wire bond 106c may be aligned in a similar configuration, while the wire bond 106b and the wire bond 106d may be aligned in another similar configuration, that is opposite to the alignments of the wire bond 106a and the wire bond 106c. Thus, the plurality of wire bonds 106 may comprises wire bonds that are aligned in an alternating pattern of a first plurality of wire bonds and a second plurality of wire bonds, where the first plurality of wire bonds (e.g., 106a, 106c) have a first configuration and the second plurality of wire bonds (e.g., 106b, 106d) have a second configuration.

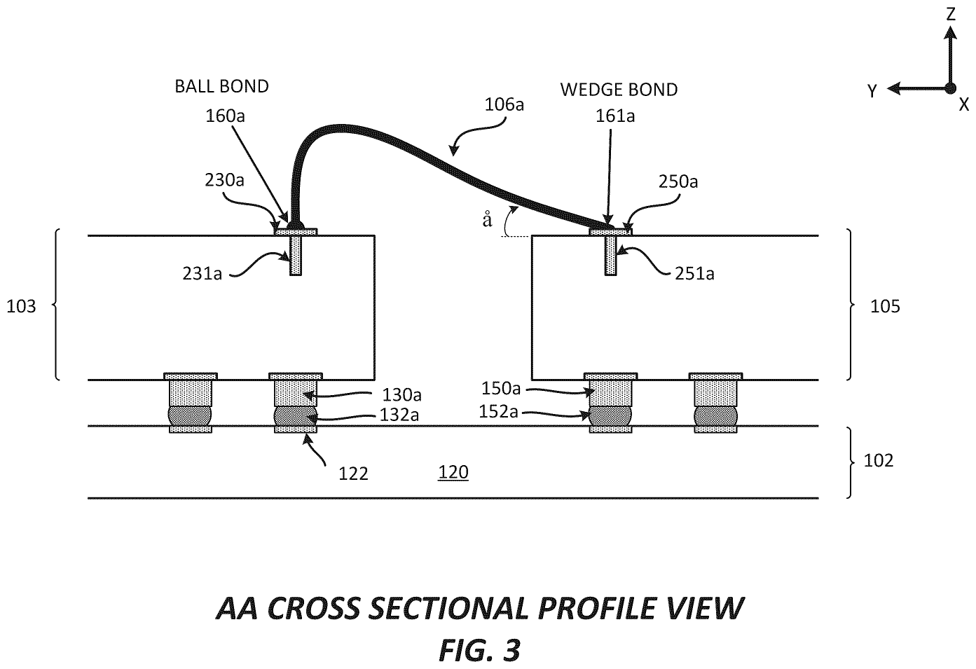

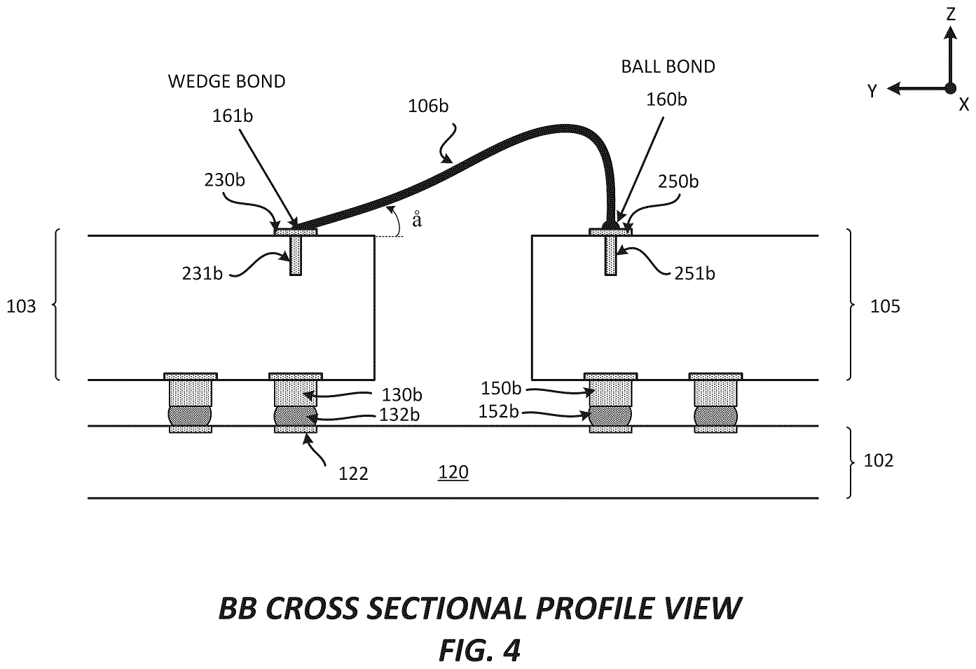

A wire bond may be coupled to a pad interconnect through a ball bond. A wire bond may be coupled to another pad interconnect through a wedge bond. The ball bond and the wedge bond may be considered part of the wire bond. The plurality of wire bonds 106 may include a plurality of ball bonds and a plurality of wedge bonds. A more detailed description of ball bonds and wedge bonds are further illustrated and described below in at least FIGS. 3 and 4.

FIG. 3 illustrates a close up view of the integrated device 103, the integrated device 105 and the plurality of wire bonds 106 through an AA cross section as shown in FIG. 2. The integrated device 103 is coupled to the substrate 102 through a pillar interconnect 130a and a solder interconnect 132a. The integrated device 103 includes a pad interconnect 230a and a through substrate via 231a. The integrated device 105 is coupled to the substrate 102 through a pillar interconnect 150a and a solder interconnect 152a. The integrated device 105 includes a pad interconnect 250a and a through substrate via 251a. The wire bond 106a is coupled to the pad interconnect 230a through the ball bond 160a. The ball bond 160a may be considered part of the wire bond 106a. The wire bond 106a is also coupled to the pad interconnect 250a through the wedge bond 161a. The wedge bond 161a may be considered part of the wire bond 106a. The configuration and/or the alignment of the wire bond 106a may start from the ball bond 160a, through the wire bond 106a and towards the wedge bond 161a. The wire bond 106a may be coupled to the pad interconnect 230a through the ball bond 160a at an angle that is approximately perpendicular to the surface of the pad interconnect 230a. The wire bond 106a may be coupled to the pad interconnect 250a through the wedge bond 161a at an angle (å) that is non-perpendicular to the surface (e.g., top surface) of the pad interconnect 250a. In some implementations, the angle (å) may be less than 45 degrees (e.g., about 30 degrees). However, the angle (å) may be different for different implementations.

An electrical path between the integrated device 103 and the integrated device 105 may include (i) the through substrate via 231a, (ii) the pad interconnect 230a, (iii) the ball bond 160a, (iv) the wire bond 106a, (v) the wedge bond 161a, (vi) the pad interconnect 250a, and/or (vii) the through substrate via 251a.

Another electrical path between the integrated device 103 and the integrated device 105 may include (i) the pillar interconnect 130a, (ii) the solder interconnect 132a, (iii) at least one interconnect from the plurality of interconnects 122, (iv) the solder interconnect 152a and/or (v) the pillar interconnect 150a.

FIG. 4 illustrates a close up view of the integrated device 103, the integrated device 105 and the plurality of wire bonds 106 through a BB cross section as shown in FIG. 2. The integrated device 103 is coupled to the substrate 102 through a pillar interconnect 130b and a solder interconnect 132b. The integrated device 103 includes a pad interconnect 230b and a through substrate via 231b. The integrated device 105 is coupled to the substrate 102 through a pillar interconnect 150b and a solder interconnect 152b. The integrated device 105 includes a pad interconnect 250b and a through substrate via 251b. The wire bond 106b is coupled to the pad interconnect 230b through the wedge bond 161b. The wedge bond 161b may be considered part of the wire bond 106b. The wire bond 106b is also coupled to the pad interconnect 250b through the ball bond 160b. The ball bond 160b may be considered part of the wire bond 106b. The configuration and/or the alignment of the wire bond 106b may start from the ball bond 160b, through the wire bond 106b and towards the wedge bond 161b. The wire bond 106b may be coupled to the pad interconnect 250b through the ball bond 160b at an angle that is approximately perpendicular to the surface of the pad interconnect 250b. The wire bond 106b may be coupled to the pad interconnect 230b through the wedge bond 161b at an angle (å) that is non-perpendicular to the surface (e.g., top surface) of the pad interconnect 230b. In some implementations, the angle (å) may be less than 45 degrees (e.g., about 30 degrees). However, the angle (å) may be different for different implementations.

An electrical path between the integrated device 103 and the integrated device 105 may include (i) the through substrate via 231b, (ii) the pad interconnect 230b, (iii) the wedge bond 161b, (iv) the wire bond 106b, (v) the ball bond 160b, (vi) the pad interconnect 250b, and/or (vii) the through substrate via 251b.

Another electrical path between the integrated device 103 and the integrated device 105 may include (i) the pillar interconnect 130b, (ii) the solder interconnect 132b, (iii) at least one interconnect from the plurality of interconnects 122, (iv) the solder interconnect 152b and/or (v) the pillar interconnect 150b.

There are several advantages to using the plurality of wire bonds 106 to provide electrical paths between integrated devices. One, it reduces the number of interconnects that are needed in the substrate 102, which may lead to a smaller substrate and potentially smaller packages. Two, the plurality of wire bonds 106 is not going to interfere with the routing of the interconnects of the substrate 102, potentially simplifying the routing of the interconnects of the substrate 102. Three, less interconnects potentially means shorter path and distances for power to various integrated devices, which may lead to improved power distribution. Four, moving at least some of the electrical paths between integrated devices outside of the substrate may lead to package impedance reduction. Five, moving at least some of the electrical path between integrated devices may lead to less parasitic introductions in the package.

### Exemplary Integrated Device

FIG. 5 illustrates a cross sectional profile view of an integrated device 500 that includes a die substrate. The integrated device 500 may represent the integrated device 103 and/or the integrated device 105. The integrated device 500 includes a die substrate portion 502 and a die interconnection portion 504. The die substrate portion 502 includes a die substrate 520, an active region 522 and a plurality of through substrate vias 521. The active region 522 may include a plurality of logic cells, a plurality of transistors, and/or a plurality of filters. Different implementations may use different types of transistors, such as a field effect transistor (FET), planar FET, finFET, and a gate all around FET. In some implementations, a front end of line (FEOL) process may be used to fabricate the active region 522 of the die substrate 520.

The die substrate 520 may include silicon (Si). The die substrate 520 may comprise a bulk silicon. The bulk silicon may include a monolith silicon. The plurality of through substrate vias 521 may extend through the die substrate 520. Different implementations may have different thicknesses for the die substrate 520.

The die interconnection portion 504 includes at least one dielectric layer 540 and a plurality of die interconnects 542. The die interconnection portion 504 is coupled to the die substrate portion 502. The plurality of die interconnects 542 is coupled to the active region 522 of the die substrate portion 502. The plurality of die interconnects 542 may be coupled to the plurality of through substrate vias 521. The die interconnection portion 504 may also include a plurality of pad interconnects 501 and a passivation layer 506. In some implementations, a back end of line (BEOL) process may be used to fabricate the die interconnection portion 504. A plurality of metallization interconnects 523 may be coupled to the plurality of through substrate vias 521. The plurality of metallization interconnects 523 may be part of a back side metallization portion of the integrated device 500. In some implementations, a front side of the integrated device 500 may be a side that includes the plurality of pad interconnects 501. In some implementations, a back side of the integrated device 500 may be a side that includes the die substrate 520, the plurality of through substrate vias 521 and/or the plurality of metallization interconnects 523. The plurality of metallization interconnects 523 may include pad interconnects (e.g., 230, 250).

In some implementations, an electrical path to and/or from an active region 522 may include at least one die interconnect from the plurality of die interconnects 542, at least one through substrate via from the plurality of through substrate vias 521. In some implementations, an electrical path to and/or from an active region 522 may include at least one die interconnect from the plurality of die interconnects 542, at least one pad interconnect from the plurality of pad interconnects 501.

An integrated device (e.g., 103, 105) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc. . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

### Exemplary Packages Comprising a Substrate, Integrated Devices and Wire Bonds

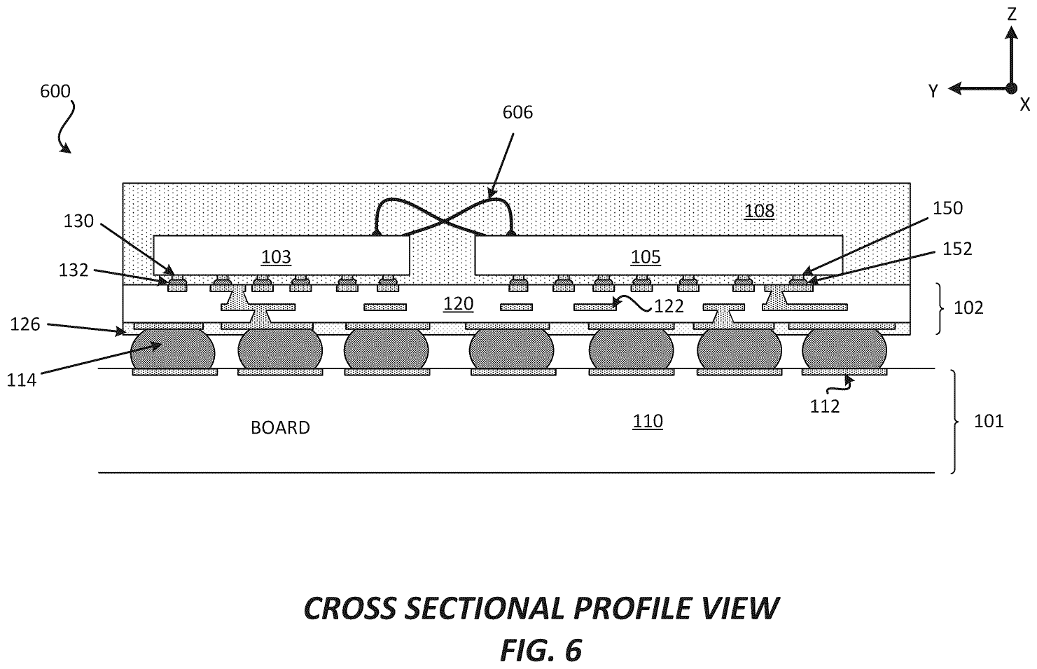

FIG. 6 illustrates a cross sectional profile view of a package 600 that includes wire bonds between integrated devices. The package 600 may be implemented as part of a package on package (PoP). The package 600 is coupled to a board 101 through a plurality of solder interconnects 114. The board 101 includes at least one board dielectric layer 110 and a plurality of board interconnects 112. The board 101 may include a printed circuit board (PCB). The package 600 is similar to the package 100, and may include similar components that are arranged in a similar manner as the package 100. The package 600 includes a plurality of wire bonds 606 that are arranged in a different configuration from the plurality of wire bonds 106 of the package 100.

The package 600 includes a substrate 102, an integrated device 103, an integrated device 105, a plurality of wire bonds 606 and an encapsulation layer 108. The substrate 102 includes a dielectric layer 120, a plurality of interconnects 122 and a solder resist layer 126. The substrate 102 is coupled to the board 101 through the plurality of solder interconnects 114. The integrated device 103 is coupled to the substrate 102 through at least a plurality of solder interconnects 132. For example, the integrated device 103 is coupled to a plurality of interconnects 122 of the substrate 102 through a plurality of pillar interconnects 130 and/or a plurality of solder interconnects 132. The integrated device 105 is coupled to the substrate 102 through at least a plurality of solder interconnects 152. For example, the integrated device 105 is coupled to a plurality of interconnects 122 of the substrate 102 through a plurality of pillar interconnects 150 and/or a plurality of solder interconnects 152.

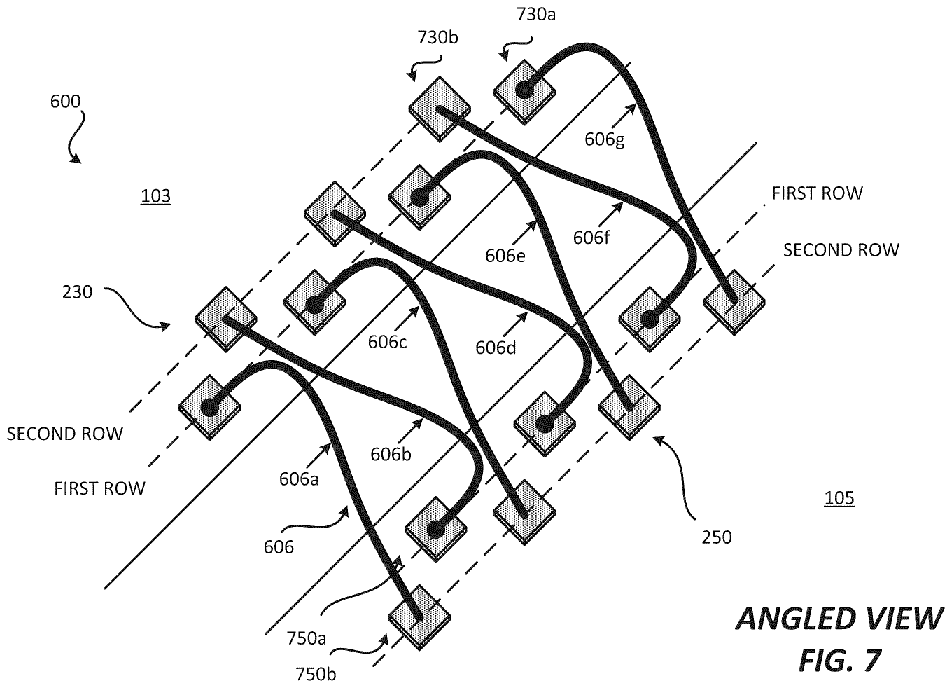

The plurality of wire bonds 606 are coupled to the integrated device 103 (e.g., first integrated device) and the integrated device 105 (e.g., second integrated device). For example, the plurality of wire bonds 606 may be coupled to a back side of the integrated device 103 and a back side of the integrated device 105. The plurality of wire bonds 606 may be configured to provide electrical paths between the integrated device 103 and the integrated device 105. The plurality of wire bonds 606 may include copper (Cu) and/or gold (Au). However, different implementations may use different metals and/or electrically conductive materials for the plurality of wire bonds 606. As will be further described below in at least FIG. 7, the plurality of wire bonds 606 are coupled to the integrated devices in an offsetting configuration, which may allow for more densely packed wire bonds.

The encapsulation layer 108 is coupled to the substrate 102. The encapsulation layer 108 may at least partially encapsulate the integrated device 103, the integrated device 105 and the plurality of wire bonds 606. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

FIG. 7 illustrates a close up view of the plurality of wire bonds 606 that are coupled to the integrated device 103 and the integrated device 105 of the package 600. As shown in FIG. 7, the integrated device 103 includes a plurality of pad interconnects 230, and the integrated device 105 includes a plurality of pad interconnects 250. The plurality of pad interconnects 230 may be located on the back side of the integrated device 103. The plurality of pad interconnects 230 may be part of a back side metallization portion of the integrated device 103. The plurality of pad interconnects 230 may be coupled to through substrate vias of the integrated device 103. The plurality of pad interconnects 250 may be located on the back side of the integrated device 105. The plurality of pad interconnects 250 may be part of a back side metallization portion of the integrated device 105. The plurality of pad interconnects 250 may be coupled to through substrate vias of the integrated device 105.

The plurality of pad interconnects 230 may include a first plurality of first pad interconnects 730a and a second plurality of first pad interconnects 730b. The first plurality of first pad interconnects 730a are arranged in a first row along an edge of the integrated device 103. The second plurality of first pad interconnects 730b are arranged in a second row along an edge of the integrated device 103. The second plurality of first pad interconnects 730b is offset from the first plurality of first pad interconnects 730a.

The plurality of pad interconnects 250 may include a first plurality of second pad interconnects 750a and a second plurality of second pad interconnects 750b. The first plurality of second pad interconnects 750a are arranged in a first row along an edge of the integrated device 105. The second plurality of second pad interconnects 750b are arranged in a second row along an edge of the integrated device 105. The second plurality of second pad interconnects 750b is offset from the first plurality of second pad interconnects 750a.

The plurality of wire bonds 606 includes a wire bond 606a, a wire bond 606b, a wire bond 606c, a wire bond 606d, a wire bond 606e, and a wire bond 606f. Some of the wire bonds from the plurality of wire bonds 606 are coupled to (i) the plurality of first pad interconnects 730a of the integrated device 103 and (ii) the plurality of second pad interconnects 750a of the integrated device 105. Some of the wire bonds from the plurality of wire bonds 606 are coupled to (i) the plurality of first pad interconnects 730b of the integrated device 103 and (ii) the plurality of second pad interconnects 750b of the integrated device 105.

The wire bond 606a may be coupled to (i) a pad interconnect from the first plurality of first pad interconnects 730a through a ball bond, and (ii) a pad interconnect from the first plurality of second pad interconnects 750a through a wedge bond.

The wire bond 606b may be coupled to (i) a pad interconnect from the second plurality of first pad interconnects 730b through a wedge bond, and (ii) a pad interconnect from the second plurality of second pad interconnects 750b through a ball bond. The wire bond 606c may be coupled to (i) another pad interconnect from the first plurality of first pad interconnects 730a through a ball bond, and (ii) another pad interconnect from the first plurality of second pad interconnects 750a through a wedge bond. The wire bond 606d may be coupled to (i) another pad interconnect from the second plurality of first pad interconnects 730b through a wedge bond, and (ii) another pad interconnect from the second plurality of second pad interconnects 750b through a ball bond. The wire bond 606e may be coupled to (i) another pad interconnect from the first plurality of first pad interconnects 730a through a ball bond, and (ii) another pad interconnect from the first plurality of second pad interconnects 750a through a wedge bond. The wire bond 606f may be coupled to (i) another pad interconnect from the second plurality of first pad interconnects 730b through a wedge bond, and (ii) another pad interconnect from the second plurality of second pad interconnects 750b through a ball bond. The wire bond 606g may be coupled to (i) another pad interconnect from the first plurality of first pad interconnects 730a through a ball bond, and (ii) another pad interconnect from the first plurality of second pad interconnects 750a through a wedge bond.

FIG. 7 illustrates that the wire bonds from the plurality of wire bonds 606 may be oriented in different alignments, directions and/or configurations. In one example, the wire bonds may alternate back in forth and worth in different alignments. For example, the wire bond 606a, the wire bond 606c, the wire bond 606f and the wire bond 606g may be aligned in a similar configuration, while the wire bond 606b, the wire bond 606d and the wire bond 606f may be aligned in another similar configuration, that is opposite to the alignments of the wire bond 606a, the wire bond 606c, the wire bond 606e and the wire bond 606g. Thus, the plurality of wire bonds 606 may comprises wire bonds that are aligned in an alternating pattern of a first plurality of wire bonds and a second plurality of wire bonds, where the first plurality of wire bonds (e.g., 606a, 606c, 606e, 606g) have a first configuration and the second plurality of wire bonds (e.g., 606b, 606d, 606f) have a second configuration.

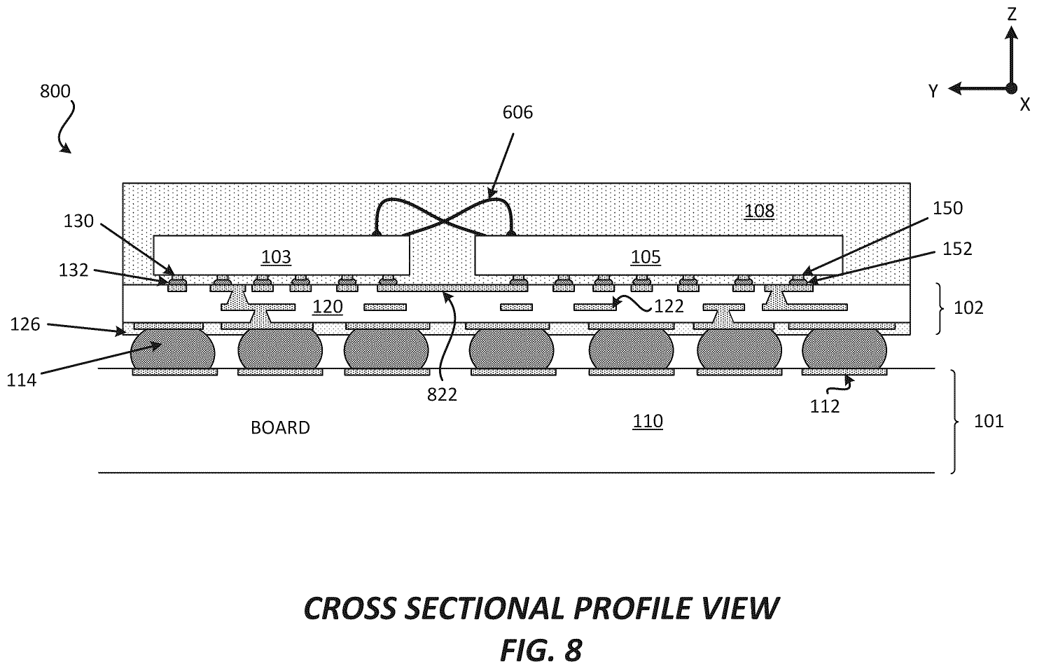

FIG. 8 illustrates a cross sectional profile view of a package 800 that includes wire bonds between integrated devices. The package 800 is similar to the package 600, and may include similar components that are arranged in a similar manner as the package 600. The package 800 includes a substrate 102 that comprises a plurality of interconnects 822. The plurality of interconnects 822 may be considered part of the plurality of interconnects 122 of the substrate 102. The integrated device 103 and the integrated device 105 may be configured to be electrically coupled to each other through the plurality of interconnects 822 of the substrate 102. Thus, in addition to at least one electrical path between the integrated device 103 and the integrated device 105 through the plurality of wire bonds 606, the integrated device 103 and the integrated device 105 may be configured to be electrically coupled through interconnects of the substrate 102.

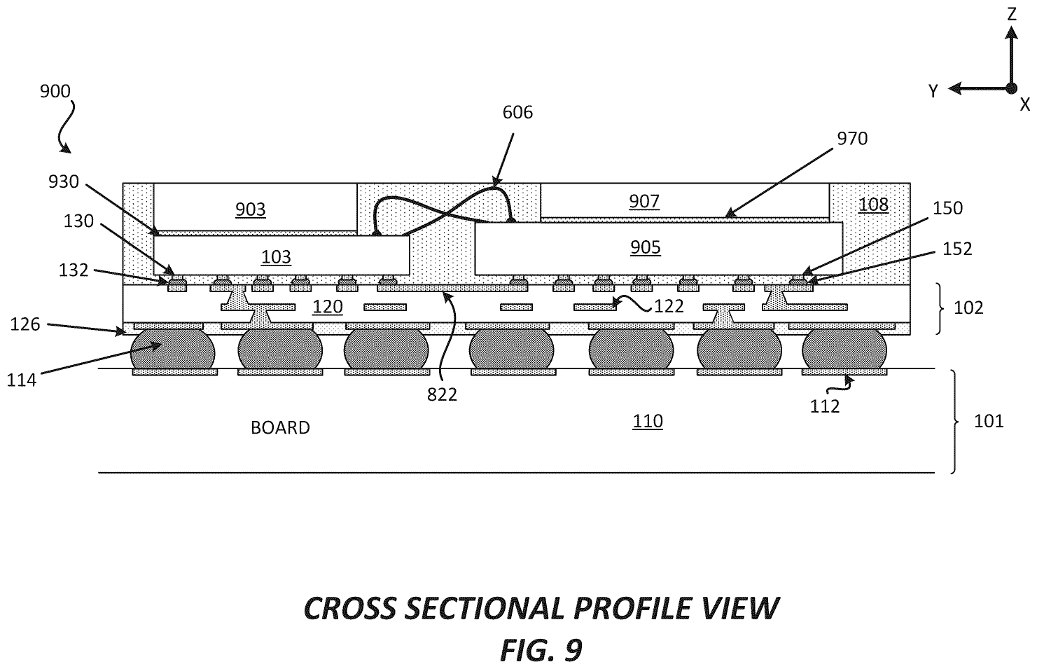

FIG. 9 illustrates a cross sectional profile view of a package 900 that includes wire bonds between integrated devices. The package 900 is similar to the package 600 and/or the package 800, and may include similar components that are arranged in a similar manner as the package 600 and/or the package 800.

The package 900 includes a substrate 102, an integrated device 103, an integrated device 905, a plurality of wire bonds 606, a heat sink 903, a heat sink 907 and an encapsulation layer 108. The heat sink 903 is coupled to the back side of the integrated device 103 through an adhesive 930. The heat sink 907 is coupled to the back side of the integrated device 905 through an adhesive 970. The heat sink 903 and/or the heat sink 907 may include copper (Cu) and/or silicon (Si). The heat sink 903 is configured to help dissipate heat away from the integrated device 103. The heat sink 907 is configured to help dissipate heat away from the integrated device 905. The adhesive 930 and/or the adhesive 970 may include a thermal interface material (TIM). The integrated device 905 is thicker than the integrated device 103. In some implementations, the integrated device 103 may be thicker than the integrated device 905. The integrated device 905 may be similar to the integrated device 105 and may include similar components that are arranged in a similar manner as the integrated device 105. The encapsulation layer 108 may at least partially encapsulate the integrated device 103, the integrated device 905, the plurality of wire bonds 606, the heat sink 903 and/or the heat sink 907.

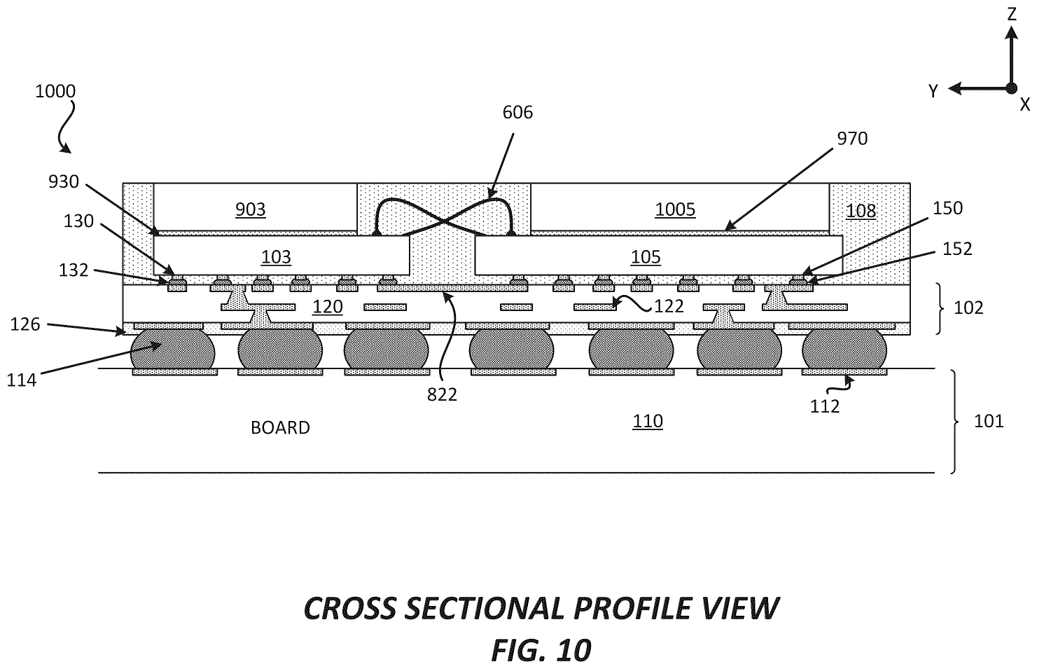

FIG. 10 illustrates a cross sectional profile view of a package 1000 that includes wire bonds between integrated devices. The package 1000 is similar to the package 600, the package 800 and/or the package 900, and may include similar components that are arranged in a similar manner as the package 600, the package 800 and/or the package 900.

The package 1000 includes a substrate 102, an integrated device 103, an integrated device 105, a plurality of wire bonds 606, a heat sink 903, a heat sink 1005 and an encapsulation layer 108. The heat sink 903 is coupled to the back side of the integrated device 103 through an adhesive 930. The heat sink 1005 is coupled to the back side of the integrated device 105 through an adhesive 970. The heat sink 903 and/or the heat sink 1005 may include copper (Cu) and/or silicon (Si). The heat sink 903 is configured to help dissipate heat away from the integrated device 103. The heat sink 1005 is configured to help dissipate heat away from the integrated device 105. The adhesive 930 and/or the adhesive 970 may include a thermal interface material (TIM). The integrated device 105 may have about the same thickness as the integrated device 103.

### Exemplary Packages Comprising a Substrate, Integrated Devices and a Flexible Cable

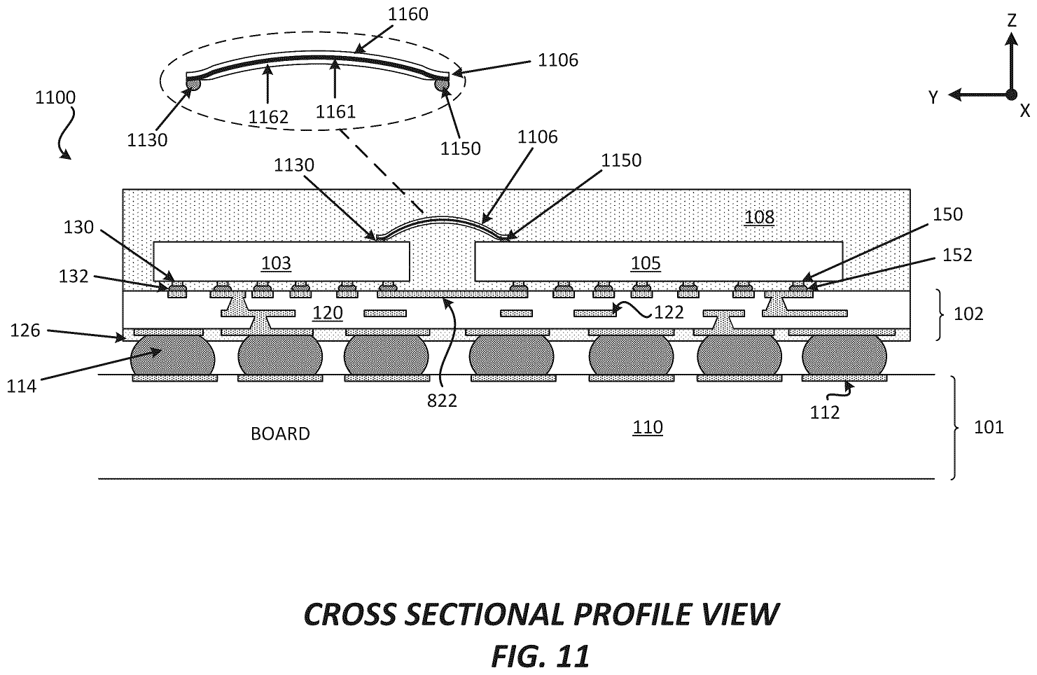

FIG. 11 illustrates a cross sectional profile view of a package 1100 that includes wire bonds between integrated devices. The package 1100 may be implemented as part of a package on package (PoP). The package 1100 is coupled to a board 101 through a plurality of solder interconnects 114. The board 101 includes at least one board dielectric layer 110 and a plurality of board interconnects 112. The board 101 may include a printed circuit board (PCB).

The package 1100 includes a substrate 102, an integrated device 103, an integrated device 105, a flexible cable 1106 and an encapsulation layer 108. The substrate 102 includes a dielectric layer 120, a plurality of interconnects 122 and a solder resist layer 126. The substrate 102 is coupled to the board 101 through the plurality of solder interconnects 114. The integrated device 103 is coupled to the substrate 102 through at least a plurality of solder interconnects 132. For example, the integrated device 103 is coupled to a plurality of interconnects 122 of the substrate 102 through a plurality of pillar interconnects 130 and/or a plurality of solder interconnects 132. The integrated device 105 is coupled to the substrate 102 through at least a plurality of solder interconnects 152. For example, the integrated device 105 is coupled to a plurality of interconnects 122 of the substrate 102 through a plurality of pillar interconnects 150 and/or a plurality of solder interconnects 152.

In some implementations, the integrated device 103 may be configured to be electrically coupled to the integrated device 105 through the substrate 102. For example, the integrated device 103 may be configured to be electrically coupled to the integrated device 105 through an electrical path that includes (i) a pillar interconnect from the plurality of pillar interconnects 130, (ii) a solder interconnect from the plurality of solder interconnects 132, (iii) at least one interconnect (e.g., 822) from the substrate 102, (iv) a solder interconnect from the plurality of solder interconnects 152 and/or (v) a pillar interconnect from the plurality of pillar interconnects 150.

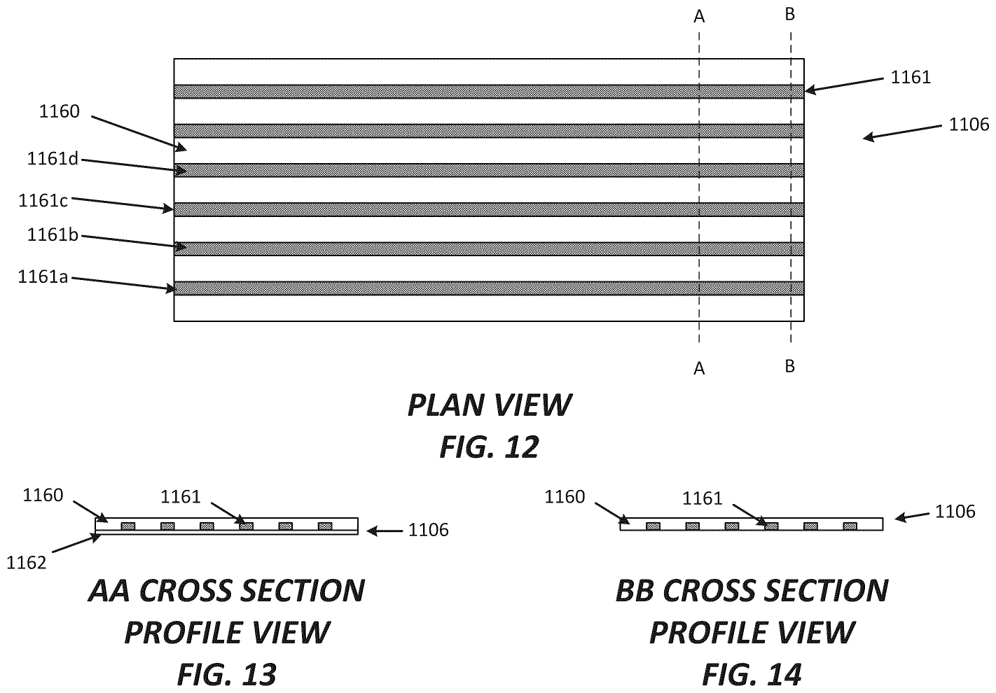

The flexible cable 1106 is coupled to the integrated device 103 (e.g., first integrated device) and the integrated device 105 (e.g., second integrated device). For example, the flexible cable 1106 may be coupled to a back side of the integrated device 103 and a back side of the integrated device 105. The flexible cable 1106 may be coupled to pad interconnects (e.g., 230) of the integrated device 103 through a plurality of solder interconnects 1130. The flexible cable 1106 may be coupled to pad interconnects (e.g., 250) of the integrated device 105 through a plurality of solder interconnects 1150. The flexible cable 1106 may include a plurality of cable interconnects 1161, a cable dielectric layer 1160 and a cable dielectric layer 1162. The cable dielectric layer 1160 and the cable dielectric layer 1162 may be considered part of the same cable dielectric layer of the flexible cable 1106. The flexible cable 1106 may be configured to provide electrical paths between the integrated device 103 and the integrated device 105. A more detailed example of a flexible cable 1106 is further illustrated and described below in at least FIGS. 12-14.

The integrated device 103 may be configured to be electrically coupled to the integrated device 105 through an electrical path that includes (i) a solder interconnect from the plurality of solder interconnects 1130, (ii) at least one cable interconnect from the plurality of cable interconnects 1161 and/or (iii) a solder interconnect from the plurality of solder interconnects 1130.

FIGS. 12-14 illustrate various views of the flexible cable 1106. FIG. 12 illustrates a plan view of the flexible cable 1106. FIG. 13 illustrates an AA cross sectional view of the flexible cable 1106 of FIG. 12. FIG. 14 illustrates a BB cross sectional view of the flexible cable 1106 of FIG. 12. The flexible cable 1106 includes a plurality of cable interconnects 1161 and the cable dielectric layer 1160. The plurality of cable interconnects 1161 includes a cable interconnect 1161a, a cable interconnect 1161b, a cable interconnect 1161c, and a cable interconnect 1161d. The plurality of cable interconnects 1161 are arranged in rows of cable interconnects. The plurality of cable interconnects 1161 may be coupled to solder interconnects (e.g., 1130, 1150) as described in FIG. 11.

The encapsulation layer 108 is coupled to the substrate 102. The encapsulation layer 108 may at least partially encapsulate the integrated device 103, the integrated device 105 and the plurality of wire bonds 106. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

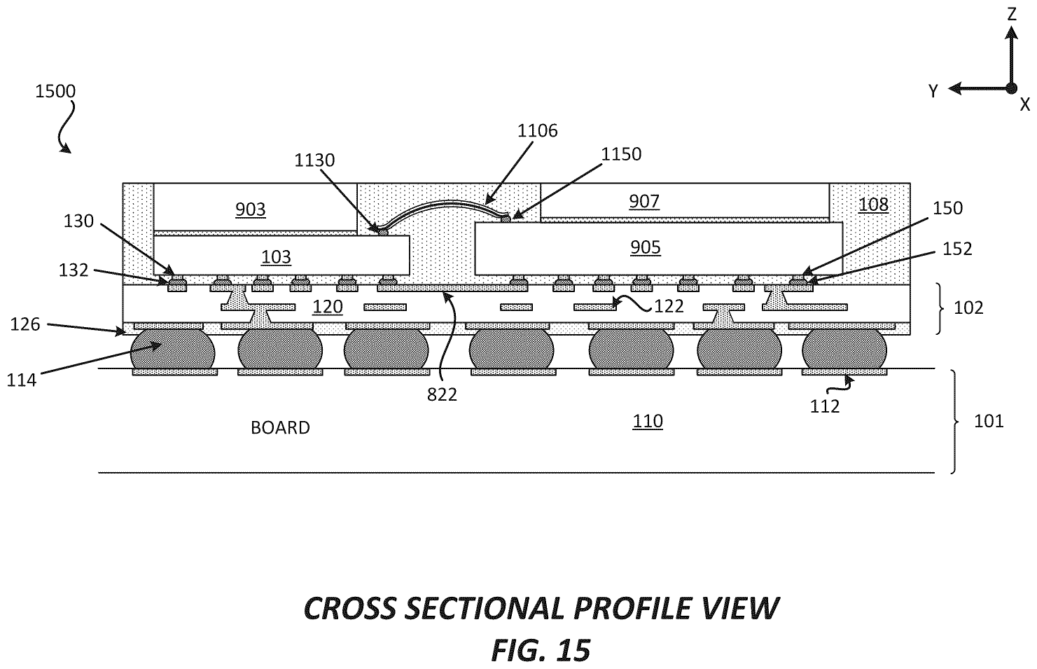

FIG. 15 illustrates a cross sectional profile view of a package 1500 that includes a flexible cable between integrated devices. The package 1500 is similar to the package 1100, and may include similar components that are arranged in a similar manner as the package 1100.

The package 1500 includes a substrate 102, an integrated device 103, an integrated device 905, a flexible cable 1106, a heat sink 903, a heat sink 907 and an encapsulation layer 108. The heat sink 903 is coupled to the back side of the integrated device 103 through an adhesive 930. The heat sink 907 is coupled to the back side of the integrated device 905 through an adhesive 970. The heat sink 903 and/or the heat sink 907 may include copper (Cu) and/or silicon (Si). The heat sink 903 is configured to help dissipate heat away from the integrated device 103. The heat sink 907 is configured to help dissipate heat away from the integrated device 905. The adhesive 930 and/or the adhesive 970 may include a thermal interface material (TIM). The integrated device 905 is thicker than the integrated device 103. In some implementations, the integrated device 103 may be thicker than the integrated device 905. The integrated device 905 may be similar to the integrated device 105 and may include similar components that are arranged in a similar manner as the integrated device 105. The encapsulation layer 108 may at least partially encapsulate the integrated device 103, the integrated device 905, the plurality of wire bonds 606, the heat sink 903 and/or the heat sink 907.

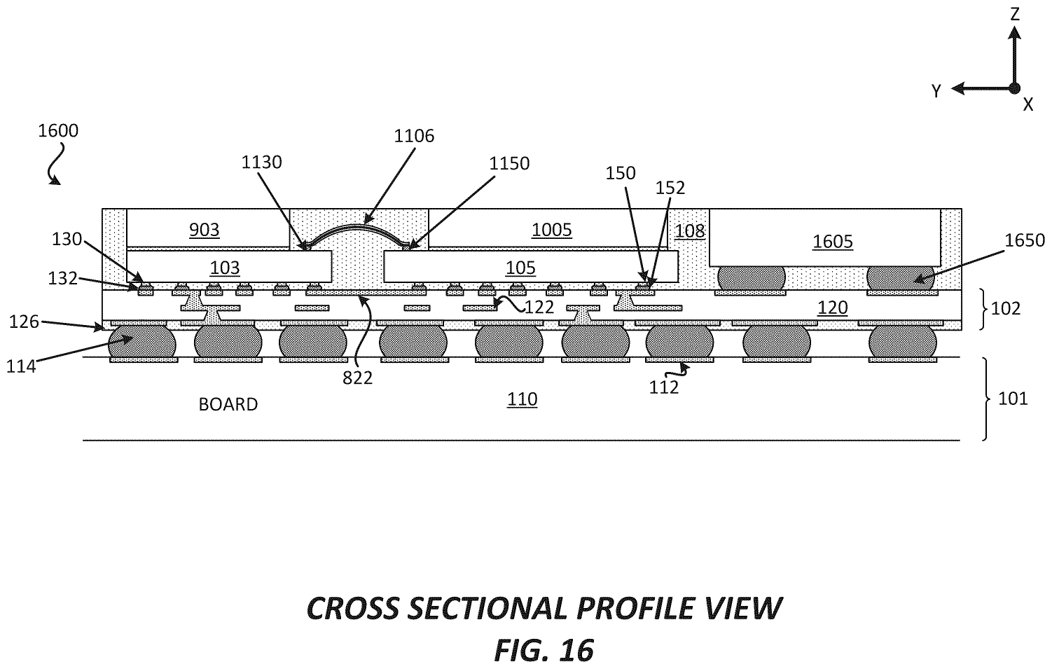

In some implementations, a package may include more components. FIG. 16 illustrates a cross sectional profile view of a package 1600 that includes a flexible cable between integrated devices. The package 1600 is similar to the package 1100 and/or the package 1500, and may include similar components that are arranged in a similar manner as the package 1100 and/or the package 1500. The package 1600 includes a substrate 102, an integrated device 103, an integrated device 105, a flexible cable 1106, a heat sink 903, a heat sink 1005, an integrated device 1605 and an encapsulation layer 108. The heat sink 903 is coupled to the back side of the integrated device 103 through an adhesive 930. The heat sink 1005 is coupled to the back side of the integrated device 105 through an adhesive 970. The heat sink 903 and/or the heat sink 1005 may include copper (Cu) and/or silicon (Si). The heat sink 903 is configured to help dissipate heat away from the integrated device 103. The heat sink 1005 is configured to help dissipate heat away from the integrated device 105. The adhesive 930 and/or the adhesive 970 may include a thermal interface material (TIM). The integrated device 105 may have about the same thickness as the integrated device 103. The integrated device 1605 may be coupled to the substrate 102 through a plurality of solder interconnects 1650. The integrated device 1605 may include memory (SRAM). The encapsulation layer 108 may at least partially encapsulate the integrated device 103, the integrated device 105, the integrated device 1605, the flexible cable 1106, the heat sink 903 and the heat sink 1005. The integrated device 1605 may be configured to be electrically coupled to the integrated device 103 and/or the integrated device 105 through at least interconnects of the substrate 102.

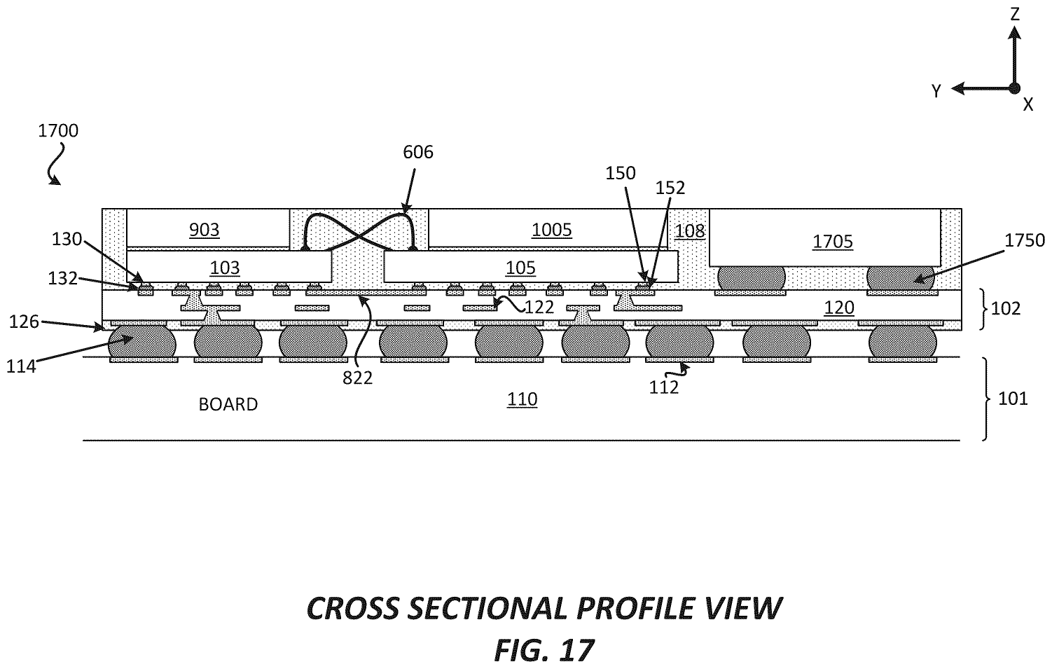

FIG. 17 illustrates a package 1700. The package 1700 is similar to the package 1000 of FIG. 10, and may include similar components that are arranged in a similar manner as the package 1000. The package 1700 includes a substrate 102, an integrated device 103, an integrated device 105, and integrated device 1705, a plurality of wire bonds 606, a heat sink 903, a heat sink 1005 and an encapsulation layer 108. The heat sink 903 is coupled to the back side of the integrated device 103 through an adhesive 930. The heat sink 1005 is coupled to the back side of the integrated device 105 through an adhesive 970. The heat sink 903 and/or the heat sink 1005 may include copper (Cu) and/or silicon (Si). The heat sink 903 is configured to help dissipate heat away from the integrated device 103. The heat sink 1005 is configured to help dissipate heat away from the integrated device 105. The adhesive 930 and/or the adhesive 970 may include a thermal interface material (TIM). The integrated device 1705 may be coupled to the substrate 102 through a plurality of solder interconnects 1750. The integrated device 1705 may include memory (SRAM). The encapsulation layer 108 may at least partially encapsulate the integrated device 103, the integrated device 105, the integrated device 1705, the plurality of wire bonds 606, the heat sink 903 and the heat sink 1005. The integrated device 1705 may be configured to be electrically coupled to the integrated device 103 and/or the integrated device 105 through at least interconnects of the substrate 102.

The package (e.g., 100, 600, 1100, 1600, 1700) may be implemented in a radio frequency (RF) package. The RF package may be a radio frequency front end (RFFE) package. A package (e.g., 100, 600) may be configured to provide Wireless Fidelity (WiFi) communication and/or cellular communication (e.g., 2G, 3G, 4G, 5G). The packages (e.g., 100, 600) may be configured to support Global System for Mobile (GSM) Communications, Universal Mobile Telecommunications System (UMTS), and/or Long-Term Evolution (LTE). The packages (e.g., 100, 600) may be configured to transmit and receive signals having different frequencies and/or communication protocols.

### Exemplary Sequence for Fabricating a Package Comprising a Substrate, Integrated Devices and Wire Bonds

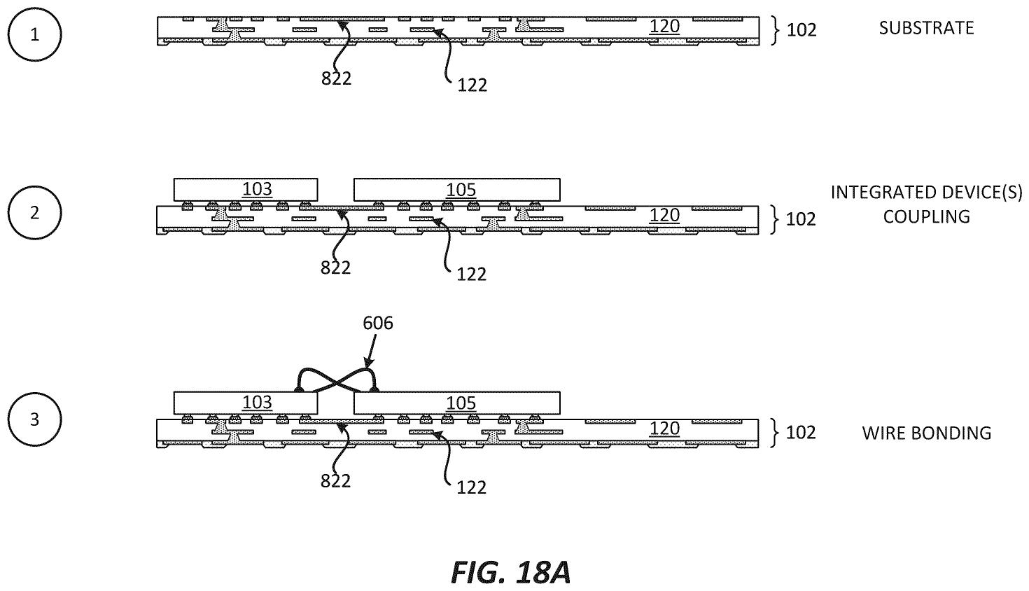

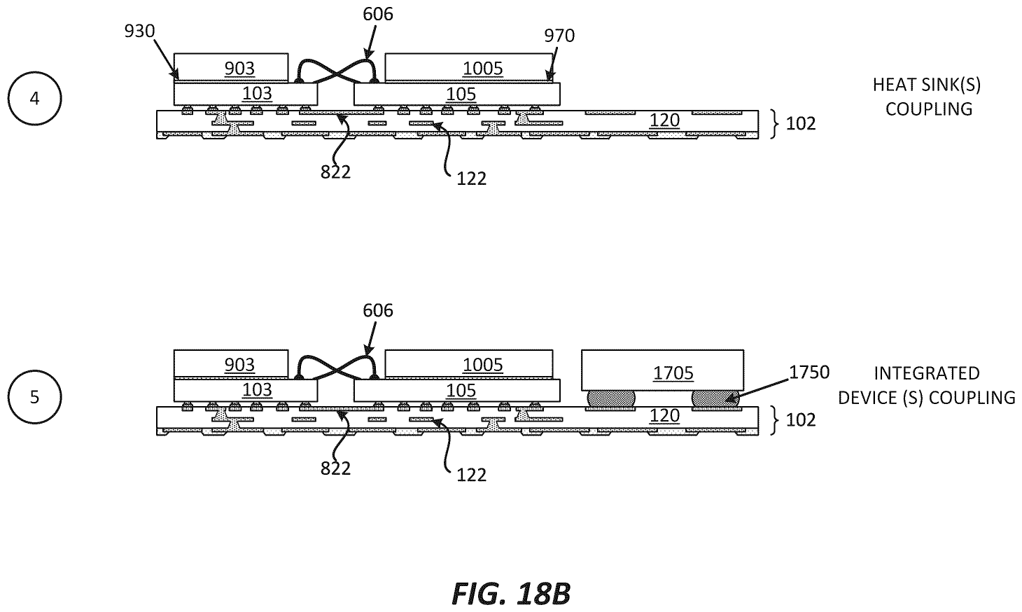

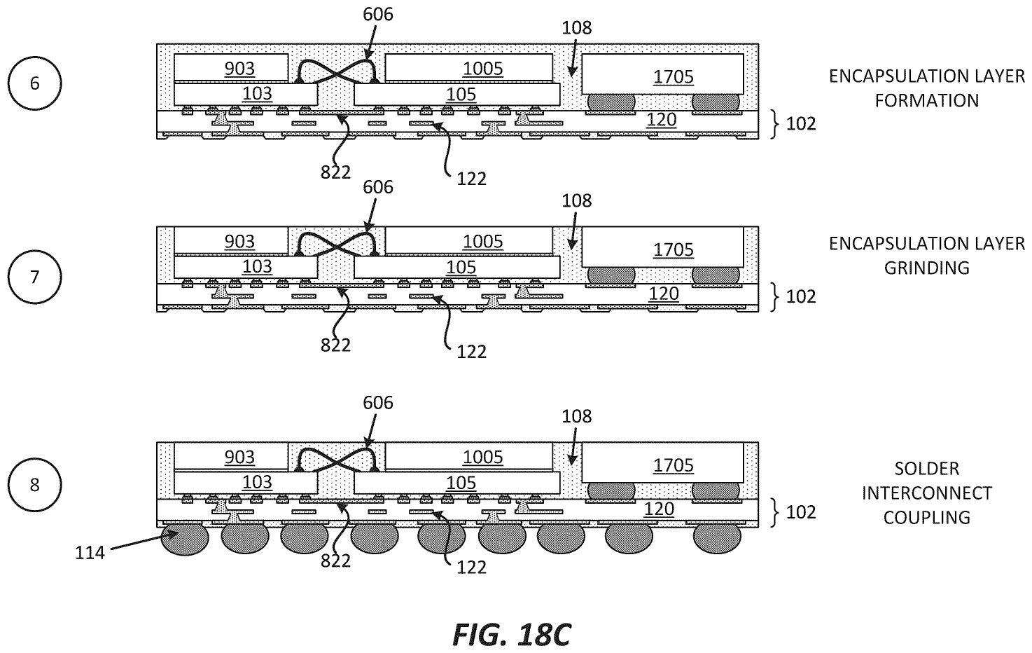

In some implementations, fabricating a package includes several processes. FIGS. 18A-18C illustrate an exemplary sequence for providing or fabricating a package. In some implementations, the sequence of FIGS. 18A-18C may be used to provide or fabricate the package 1700. However, the process of FIGS. 18A-18C may be used to fabricate any of the packages (e.g., 100, 1100, 1600) described in the disclosure.

It should be noted that the sequence of FIGS. 18A-18C may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

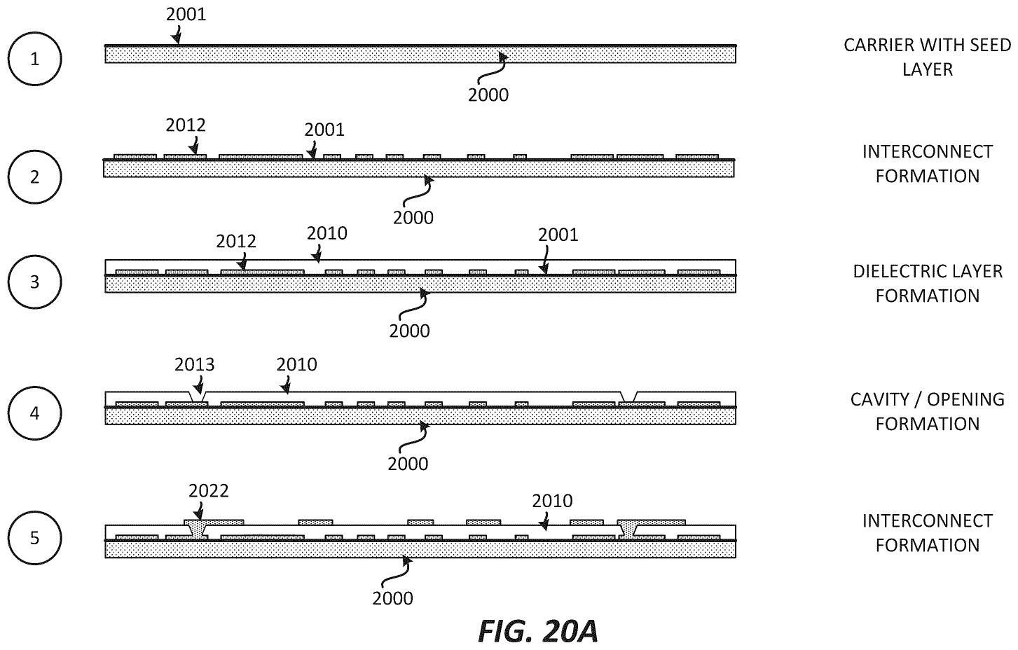

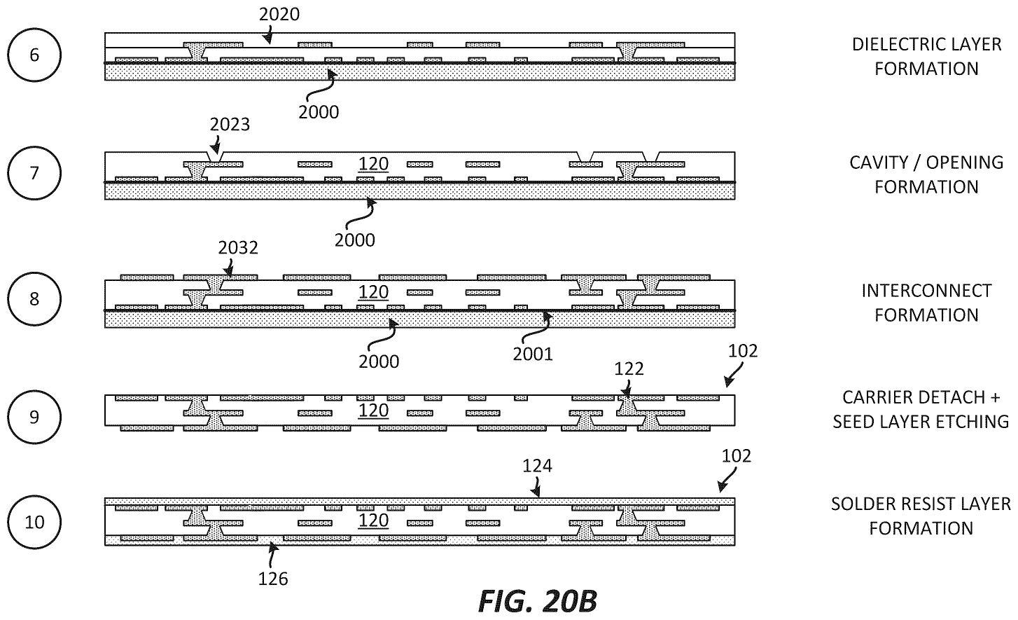

Stage 1, as shown in FIG. 18A, illustrates a state after a substrate 102 is provided. The substrate 102 may be a first substrate. The substrate 102 includes at least one dielectric layer 120, a plurality of interconnects 122 and a plurality of interconnects 822. The plurality of interconnects 822 may be considered part of the plurality of interconnects 122. The substrate 102 may include a first surface (e.g., top surface) and a second surface (e.g., bottom surface). The substrate 912 may include solder resist layers. The substrate 102 may be fabricated using the method as described in FIGS. 20A-20B.

Stage 2 illustrates a state after an integrated device 103 is coupled to the first surface (e.g., top surface) of the substrate 102. The integrated device 103 may be coupled to the substrate 102 through the plurality of pillar interconnects 130 and the plurality of solder interconnects 132. In some implementations, the integrated device 103 may be coupled to the substrate 102 through the plurality of solder interconnects 132. A solder reflow process may be used to couple the integrated device 103 to the substrate 102.

Stage 2 also illustrates a state after an integrated device 105 is coupled to the first surface (e.g., top surface) of the substrate 102. The integrated device 105 may be coupled to the substrate 102 through the plurality of pillar interconnects 150 and the plurality of solder interconnects 152. In some implementations, the integrated device 105 may be coupled to the substrate 102 through the plurality of solder interconnects 152. A solder reflow process may be used to couple the integrated device 105 to the substrate 102.

Stage 3 illustrates a state after a plurality of wire bonds 606 are formed and coupled to the integrated device 103 and the integrated device 105. A drawing process may be used to form the plurality of wire bonds 606. The plurality of wire bonds 606 may be coupled to the back side of the integrated device 103 and the back side of the integrated device 105. For example, the plurality of wire bonds 606 may be coupled to the pad interconnects on the back side of the integrated device 103 and pad interconnects on the back side of the integrated device 105. Some of the wire bonds from the plurality of wire bonds 606 may be formed from the integrated device 103 to the integrated device 105. Some of the wire bonds from the plurality of wire bonds 606 may be formed from the integrated device 105 to the integrated device 103. A first plurality of wire bonds from the plurality of wire bonds 606 may be coupled to pad interconnects of the integrated device 103 through ball bonds. The first plurality of wire bonds from the plurality of wire bonds 606 may be coupled to pad interconnects of the integrated device 105 through wedge bonds. A second plurality of wire bonds from the plurality of wire bonds 606 may be coupled to pad interconnects of the integrated device 103 through wedge bonds. The second plurality of wire bonds from the plurality of wire bonds 606 may be coupled to pad interconnects of the integrated device 105 through ball bonds.

In some implementations, instead of the plurality of wire bonds 606, a flexible cable 1106 may be coupled to the integrated device 103 and the integrated device 105. The flexible cable 1106 may be coupled to the integrated device 103 through a first plurality of solder interconnects. The flexible cable 1106 may be coupled to the integrated device 105 through a second plurality of solder interconnects. A solder reflow process may be used to couple the flexible cable 1106 to the integrated device 103 and the integrated device 105.

Stage 4, as shown in FIG. 18B, illustrates a state after a heat sink 903 is coupled to the back side of the integrated device 103 through an adhesive 930. Stage 4 also illustrates a state after a heat sink 1005 is coupled to the back side of the integrated device 105 through an adhesive 970. The adhesive 930 and/or the adhesive 970 may include a thermal interface material (TIM).

Stage 5 illustrates a state after an integrated device 1705 is coupled to the first surface (e.g., top surface) of the substrate 102. The integrated device 1705 may be coupled to the substrate 102 through a plurality of solder interconnects 1750. A solder reflow process may be used to couple the integrated device 1705 to the substrate 102 through the plurality of solder interconnects 1750.

Stage 6, as shown in FIG. 18C, illustrates a state after an encapsulation layer 108 is provided and coupled to the substrate 102. The encapsulation layer 108 may at least partially encapsulate the integrated device 103, the integrated device 105, the integrated device 1705, the heat sink 903, the heat sink 1005 and the plurality of wire bonds 606. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

Stage 7 illustrates a state after portions of the encapsulation layer 108 are removed. A grinding process and/or a polishing process may be used to remove portions of the encapsulation layer 108.

Stage 8 illustrates a state after a plurality of solder interconnects 114 are coupled to the second surface of the substrate 102. A solder reflow process may be used to couple the plurality of solder interconnects 114 to the substrate 102. Stage 8 may illustrate the package 1700.

### Exemplary Flow Diagram of a Method for Fabricating a Package Comprising a Substrate, Integrated Devices and Wire Bonds

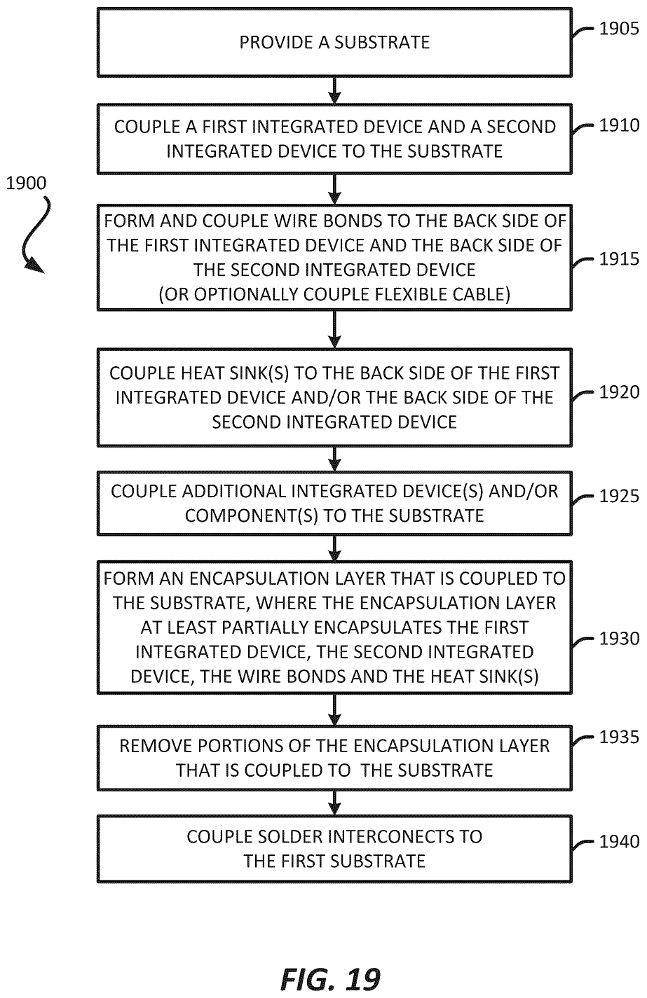

In some implementations, fabricating a package includes several processes. FIG. 19 illustrates an exemplary flow diagram of a method 1900 for providing or fabricating a package. In some implementations, the method 1900 of FIG. 19 may be used to provide or fabricate the package 1700 described in the disclosure. However, the method 1900 may be used to provide or fabricate any of the packages (e.g., 100) described in the disclosure.

It should be noted that the method 1900 of FIG. 19 may combine one or more processes in order to simplify and/or clarify the method for providing or fabricating a package. In some implementations, the order of the processes may be changed or modified.

The method provides (at 1905) a substrate. Stage 1 of FIG. 18A, illustrates and describes an example of a state after a substrate 102 is provided. The substrate 102 may be a first substrate. The substrate 102 includes at least one dielectric layer 120, a plurality of interconnects 122 and a plurality of interconnects 822. The plurality of interconnects 822 may be considered part of the plurality of interconnects 122. The substrate 102 may include a first surface (e.g., top surface) and a second surface (e.g., bottom surface). The substrate 912 may include solder resist layers. The substrate 102 may be fabricated using the method as described in FIGS. 20A-20B.

The method couples (at 1910) a first integrated device and a second integrated device to the substrate. Stage 2 of FIG. 18A, illustrates and describes an example of a state after an integrated device 103 is coupled to the first surface (e.g., top surface) of the substrate 102. The integrated device 103 may be coupled to the substrate 102 through the plurality of pillar interconnects 130 and the plurality of solder interconnects 132. In some implementations, the integrated device 103 may be coupled to the substrate 102 through the plurality of solder interconnects 132. A solder reflow process may be used to couple the integrated device 103 to the substrate 102.

Stage 2 of FIG. 18A, also illustrates and describes an example of a state after an integrated device 105 is coupled to the first surface (e.g., top surface) of the substrate 102. The integrated device 105 may be coupled to the substrate 102 through the plurality of pillar interconnects 150 and the plurality of solder interconnects 152. In some implementations, the integrated device 105 may be coupled to the substrate 102 through the plurality of solder interconnects 152. A solder reflow process may be used to couple the integrated device 105 to the substrate 102.

The method forms and couples (at 1915) a plurality of wire bonds to the first back side of the first integrated device and the second back side of the second integrated device. Stage 3 of FIG. 18A, illustrates and describes an example of a state after a plurality of wire bonds 606 are formed and coupled to the integrated device 103 and the integrated device 105. A drawing process may be used to form the plurality of wire bonds 606. The plurality of wire bonds 606 may be coupled to the back side of the integrated device 103 and the back side of the integrated device 105. For example, the plurality of wire bonds 606 may be coupled to the pad interconnects on the back side of the integrated device 103 and pad interconnects on the back side of the integrated device 105. Some of the wire bonds from the plurality of wire bonds 606 may be formed from the integrated device 103 to the integrated device 105. Some of the wire bonds from the plurality of wire bonds 606 may be formed from the integrated device 105 to the integrated device 103. A first plurality of wire bonds from the plurality of wire bonds 606 may be coupled to pad interconnects of the integrated device 103 through ball bonds. The first plurality of wire bonds from the plurality of wire bonds 606 may be coupled to pad interconnects of the integrated device 105 through wedge bonds. A second plurality of wire bonds from the plurality of wire bonds 606 may be coupled to pad interconnects of the integrated device 103 through wedge bonds. The second plurality of wire bonds from the plurality of wire bonds 606 may be coupled to pad interconnects of the integrated device 105 through ball bonds.

In some implementations, instead of the plurality of wire bonds 606, a flexible cable 1106 may be coupled to the integrated device 103 and the integrated device 105. The flexible cable 1106 may be coupled to the integrated device 103 through a first plurality of solder interconnects. The flexible cable 1106 may be coupled to the integrated device 105 through a second plurality of solder interconnects. A solder reflow process may be used to couple the flexible cable 1106 to the integrated device 103 and the integrated device 105.

The method couples (at 1920) heat sink(s) to the back side of integrated device(s). Stage 4 of FIG. 18B, illustrates and describes an example of a state after a heat sink 903 is coupled to the back side of the integrated device 103 through an adhesive 930. Stage 4 also illustrates a state after a heat sink 1005 is coupled to the back side of the integrated device 105 through an adhesive 970. The adhesive 930 and/or the adhesive 970 may include a thermal interface material (TIM).

The method couples (at 1925) additional integrated device(s) to the substrate. Stage 5 of FIG. 18B, illustrates and describes an example of a state after an integrated device 1705 is coupled to the first surface (e.g., top surface) of the substrate 102. The integrated device 1705 may be coupled to the substrate 102 through a plurality of solder interconnects 1750. A solder reflow process may be used to couple the integrated device 1705 to the substrate 102 through the plurality of solder interconnects 1750.

The method forms (at 1930) an encapsulation layer that is coupled to the substrate. Stage 6 of FIG. 18C, illustrates and describes an example of a state after an encapsulation layer 108 is provided and coupled to the substrate 102. The encapsulation layer 108 may at least partially encapsulate the integrated device 103, the integrated device 105, the integrated device 1705, the heat sink 903, the heat sink 1005 and the plurality of wire bonds 606. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

The method removes (at 1935) portions of the encapsulation layer. Stage 7 of FIG. 18C, illustrates and describes an example of a state after portions of the encapsulation layer 108 are removed. A grinding process and/or a polishing process may be used to remove portions of the encapsulation layer 108.

The method couples (at 1940) a plurality of solder interconnects to the substrate. Stage 8 of FIG. 18C, illustrates and describes an example of a state after a plurality of solder interconnects 114 are coupled to the second surface of the substrate 102. A solder reflow process may be used to couple the plurality of solder interconnects 114 to the substrate 102. Stage 8 of FIG. 18C, may illustrate the package 1700.

### Exemplary Sequence for Fabricating a Substrate

In some implementations, fabricating a substrate includes several processes. FIGS. 20A-20B illustrate an exemplary sequence for providing or fabricating a substrate. In some implementations, the sequence of FIGS. 20A-20B may be used to provide or fabricate the substrate 102. However, the process of FIGS. 20A-20B may be used to fabricate any of the substrates described in the disclosure.

It should be noted that the sequence of FIGS. 20A-20B may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 20A, illustrates a state after a carrier 2000 is provided. A seed layer 2001 may be located over the carrier 2000.

Stage 2 illustrates a state after a plurality of interconnects 2012 are formed. The interconnects 2012 may be located over the seed layer 2001. A lithography process, a plating process, a strip process and/or an etching process may be used to form the plurality of interconnects 2012. The interconnects 2012 may represent at least some of the interconnects from the plurality of interconnects 122.

Stage 3 illustrates a state after a dielectric layer 2010 is formed over the carrier 2000, the seed layer 2001 and the plurality of interconnects 2012. A deposition and/or lamination process may be used to form the dielectric layer 2010. The dielectric layer 2010 may include prepreg and/or polyimide. The dielectric layer 2010 may include a photo-imageable dielectric. However, different implementations may use different materials for the dielectric layer.

Stage 4 illustrates a state after a plurality of cavities 2013 is formed in the dielectric layer 2010. The plurality of cavities 2013 may be formed using an etching process (e.g., photo etching process), a laser process, an exposure process and/or a development process.

Stage 5 illustrates a state after interconnects 2022 are formed in and over the dielectric layer 2010, including in and over the plurality of cavities 2013. For example, a via, pad and/or traces may be formed. A lithography process, a plating process, a strip process and/or an etching process may be used to form the interconnects.

Stage 6, as shown in FIG. 20B, illustrates a state after a dielectric layer 2020 is formed over the dielectric layer 2010 and the plurality of interconnects 2022. A deposition and/or lamination process may be used to form the dielectric layer 2020. The dielectric layer 2020 may include prepreg and/or polyimide. The dielectric layer 2020 may include a photo-imageable dielectric. However, different implementations may use different materials for the dielectric layer.

Stage 7, illustrates a state after a plurality of cavities 2023 is formed in the dielectric layer 120. The dielectric layer 120 may represent the dielectric layer 2010 and/or the dielectric layer 2020. The plurality of cavities 2023 may be formed using an etching process (e.g., photo etching process), a laser process, an exposure process and/or a development process.

Stage 8 illustrates a state after interconnects 2032 are formed in and over the dielectric layer 120, including in and over the plurality of cavities 2023. For example, a via, pad and/or traces may be formed. A lithography process, a plating process, a strip process and/or an etching process may be used to form the interconnects.

Stage 9 illustrates a state after the carrier 2000 is decoupled (e.g., detached, removed, grinded out) from at least one dielectric layer 120 and the seed layer 2001, portions of the seed layer 2001 are removed (e.g., etched out), leaving the substrate 102 that includes at least one dielectric layer 120 and the plurality of interconnects 122. The plurality of interconnects 122 may represent the plurality of interconnects 2012, the plurality of interconnects 2022 and/or the plurality of interconnects 2032.

Stage 10 illustrates a state after the solder resist layer 124 is formed over the first surface of the substrate 102, and after the solder resist layer 126 is formed over the second surface of the substrate 102. A deposition process and/or lamination process may be used to form the solder resist layer 124 and/or the solder resist layer 126. The solder resist layer 124 and/or the solder resist layer 126 may include openings. An etching process, an exposure process and/or a development process may be used to form the openings in the solder resist layer 124 and/or the openings in the solder resist layer 126.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Substrate

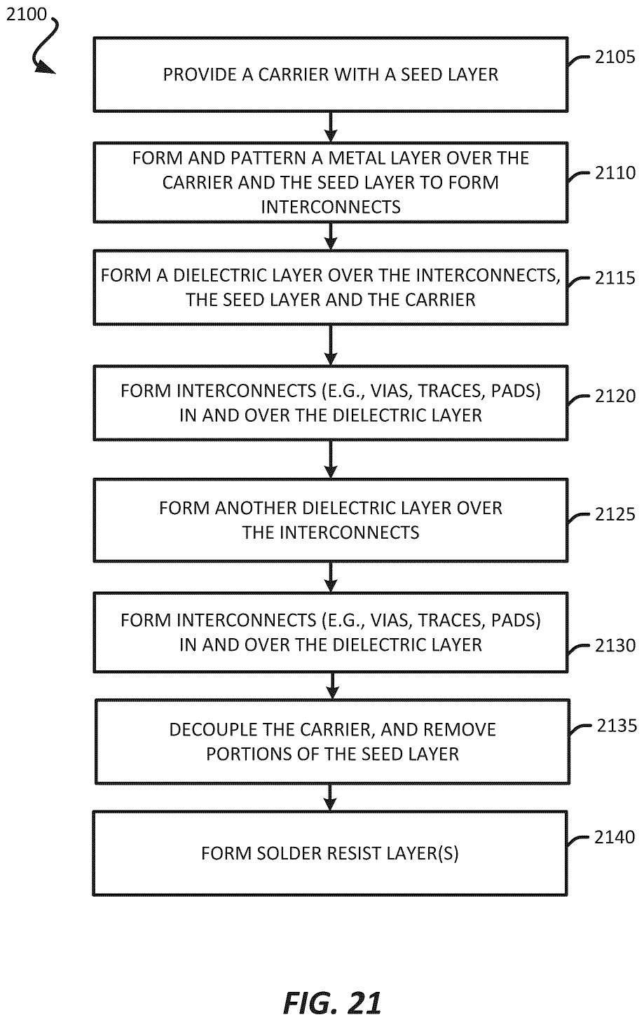

In some implementations, fabricating a substrate includes several processes. FIG. 21 illustrates an exemplary flow diagram of a method 2100 for providing or fabricating a substrate. In some implementations, the method 2100 of FIG. 21 may be used to provide or fabricate the substrate(s) of the disclosure. For example, the method 2100 of FIG. 21 may be used to fabricate the substrate 102.

It should be noted that the method 2100 of FIG. 21 may combine one or more processes in order to simplify and/or clarify the method for providing or fabricating a substrate. In some implementations, the order of the processes may be changed or modified.

The method provides (at 2105) a carrier with a seed layer. Stage 1 of FIG. 20A, illustrates and describes an example of a state after a carrier 2000 is provided. A seed layer 2001 may be located over the carrier 2000.

The method forms and patterns (at 2110) a plurality of interconnects. Stage 2 of FIG. 20A, illustrates and describes an example of a state after a plurality of interconnects 2012 are formed. The interconnects 2012 may be located over the seed layer 2001. A lithography process, a plating process, a strip process and/or an etching process may be used to form the plurality of interconnects 2012. The interconnects 2012 may represent at least some of the interconnects from the plurality of interconnects 122.

The method forms (at 2120) a dielectric layer. Stage 3 of FIG. 20A, illustrates and describes an example of a state after a dielectric layer 2010 is formed over the carrier 2000, the seed layer 2001 and the plurality of interconnects 2012. A deposition and/or lamination process may be used to form the dielectric layer 2010. The dielectric layer 2010 may include prepreg and/or polyimide. The dielectric layer 2010 may include a photo-imageable dielectric. However, different implementations may use different materials for the dielectric layer.

The method forms (at 2120) a plurality of interconnects. Forming a plurality of interconnects may including forming a plurality of cavities in a dielectric layer and a performing a plating process. Stage 4 of FIG. 20A, illustrates and describes an example of a state after a plurality of cavities 2013 is formed in the dielectric layer 2010. The plurality of cavities 2013 may be formed using an etching process (e.g., photo etching process), a laser process, an exposure process and/or a development process.

Stage 5 of FIG. 20A, illustrates and describes an example of a state after interconnects 2022 are formed in and over the dielectric layer 2010, including in and over the plurality of cavities 2013. For example, a via, pad and/or traces may be formed. A lithography process, a plating process, a strip process and/or an etching process may be used to form the interconnects.

The method forms (at 2125) another dielectric layer. Stage 6 of FIG. 20B, illustrates and describes an example of a state after a dielectric layer 2020 is formed over the dielectric layer 2010 and the plurality of interconnects 2022. A deposition and/or lamination process may be used to form the dielectric layer 2020. The dielectric layer 2020 may include prepreg and/or polyimide. The dielectric layer 2020 may include a photo-imageable dielectric. However, different implementations may use different materials for the dielectric layer.

The method forms (at 2130) a plurality of interconnects. Forming a plurality of interconnects may including forming a plurality of cavities in a dielectric layer and a performing a plating process. Stage 7 of FIG. 20B, illustrates and describes an example of a state after a plurality of cavities 2023 is formed in the dielectric layer 120. The dielectric layer 120 may represent the dielectric layer 2010 and/or the dielectric layer 2020. The plurality of cavities 2023 may be formed using an etching process (e.g., photo etching process), a laser process, an exposure process and/or a development process.

Stage 8 of FIG. 20B, illustrates and describes an example of a state after interconnects 2032 are formed in and over the dielectric layer 120, including in and over the plurality of cavities 2023. For example, a via, pad and/or traces may be formed. A lithography process, a plating process, a strip process and/or an etching process may be used to form the interconnects.

The method decouples (at 2135) a carrier. Stage 9 of FIG. 20B, illustrates and describes an example of a state after the carrier 2000 is decoupled (e.g., detached, removed, grinded out) from at least one dielectric layer 120 and the seed layer 2001, portions of the seed layer 2001 are removed (e.g., etched out), leaving the substrate 102 that includes at least one dielectric layer 120 and the plurality of interconnects 122. The plurality of interconnects 122 may represent the plurality of interconnects 2012, the plurality of interconnects 2022 and/or the plurality of interconnects 2032.

The method forms (at 2140) solder resist layers. Stage 10 of FIG. 20B, illustrates and describes an example of a state after the solder resist layer 124 is formed over the first surface of the substrate 102, and after the solder resist layer 126 is formed over the second surface of the substrate 102. A deposition process and/or lamination process may be used to form the solder resist layer 124 and/or the solder resist layer 126. An etching process, an exposure process and/or a development process may be used to form the openings in the solder resist layer 124 and/or the openings in the solder resist layer 126.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Electronic Devices

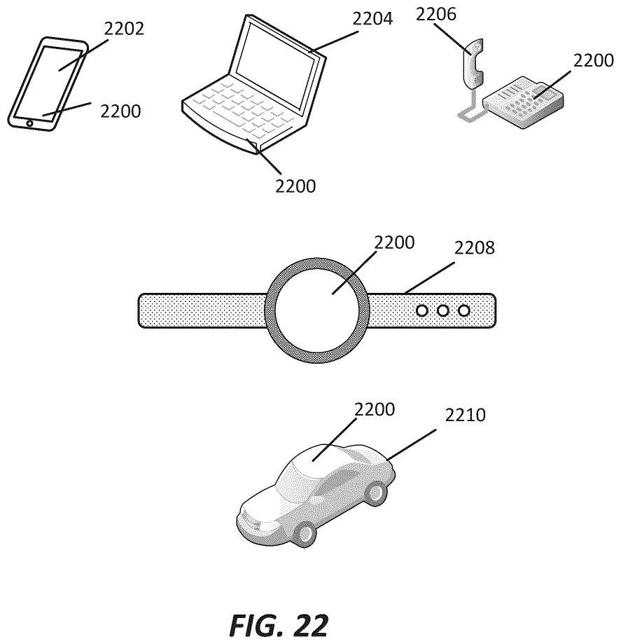

FIG. 22 illustrates various electronic devices that may be integrated with any of the aforementioned device, integrated device, integrated circuit (IC) package, integrated circuit (IC) device, semiconductor device, integrated circuit, die, interposer, package, package-on-package (POP), System in Package (SiP), or System on Chip (SoC). For example, a mobile phone device 2202, a laptop computer device 2204, a fixed location terminal device 2206, a wearable device 2208, or automotive vehicle 2210 may include a device 2200 as described herein. The device 2200 may be, for example, any of the devices and/or integrated circuit (IC) packages described herein. The devices 2202, 2204, 2206 and 2208 and the vehicle 2210 illustrated in FIG. 22 are merely exemplary. Other electronic devices may also feature the device 2200 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-17, 18A-18C, 19, 20A-20B, and 21-22 may be rearranged and/or combined into a single component, process, feature or function or embodied in several components, processes, or functions. Additional elements, components, processes, and/or functions may also be added without departing from the disclosure. It should also be noted FIGS. 1-17, 18A-18C, 19, 20A-20B, and 21-22 and its corresponding description in the present disclosure is not limited to dies and/or ICs. In some implementations, FIGS. 1-17, 18A-18C, 19, 20A-20B, and 21-22 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A package comprising a substrate; a first integrated device coupled to the substrate; a second integrated device coupled to the substrate; and a plurality of wire bonds coupled to the first integrated device and the second integrated device.

Aspect 2: The package of aspect 1, wherein the plurality of wire bonds are coupled to a first back side of the first integrated device and a second back side of the second integrated device.

Aspect 3: The package of aspects 1 through 2, wherein the plurality of wire bonds comprise a first plurality of wire bonds and a second plurality of wire bonds, wherein the first plurality of wire bonds comprise a first plurality of ball bonds and a first plurality of wedge bonds, wherein the first plurality of ball bonds are coupled to the first integrated device, wherein the first plurality of wedge bonds are coupled to the second integrated device, wherein the second plurality of wire bonds comprise a second plurality of ball bonds and a second plurality of wedge bonds, wherein the second plurality of ball bonds are coupled to the second integrated device, and wherein the second plurality of wedge bonds are coupled to the first integrated device.

Aspect 4: The package of aspect 3, wherein the first plurality of wire bonds and the second plurality of wire bonds are arranged such that wire bonds alternate between a wire bond from the first plurality of wire bonds and a wire bond from the second plurality of wire bonds.

Aspect 5: The package of aspect 3, wherein the first integrated device comprises a first row of first pad interconnects and a second row of first pad interconnects, wherein the second integrated comprises a first row of second pad interconnects and a second row of second pad interconnects, wherein the first plurality of ball bonds are coupled to the first row of first pad interconnects of the first integrated device, wherein the first plurality of wedge bonds are coupled to the second row of second pad interconnects of the second integrated device, wherein the second plurality of ball bonds are coupled to the first row of second pad interconnects of the second integrated device, and wherein the second plurality of wedge bonds are coupled to the second row of first pad interconnects of the first integrated device.

Aspect 6: The package of aspects 1 through 5, wherein a first electrical path between the first integrated device and the second integrated device includes a wire bond from the plurality of wire bonds.

Aspect 7: The package of aspect 6, wherein a second electrical path between the first integrated device and the second integrated device includes at least one interconnect from the substrate.

Aspect 8: The package of aspects 1 through 7, further comprising a heat sink coupled to a back side of the first integrated device.

Aspect 9: The package of aspect 8, wherein the heat sink is coupled to the back side of the first integrated device through an adhesive.

Aspect 10: The package of aspect 8, wherein the heat sink comprise copper (Cu) and/or silicon (Si).

Aspect 11: The package of aspects 1 through 10, wherein the first integrated device is coupled to the substrate through a first plurality of pillar interconnects and a first plurality of solder interconnects, and wherein the second integrated device is coupled to the substrate through a second plurality of pillar interconnects and a second plurality of solder interconnects.

Aspect 12: The package of aspect 11, wherein a first electrical path between the first integrated device and the second integrated device includes a wire bond from the plurality of wire bonds, and wherein a second electrical path between the first integrated device and the second integrated device includes (i) a pillar interconnect from the first plurality of pillar interconnects, (ii) a solder interconnect from the first plurality of solder interconnects, (iii) at least one interconnect from the substrate, (iv) a solder interconnect from the second plurality of solder interconnects, and/or (v) a pillar interconnect from the second plurality of pillar interconnects.

Aspect 13: The package of aspects 1 through 12, wherein the first integrated device includes a first thickness and the second integrated device includes a second thickness that is different from the first thickness.

Aspect 14: A package comprising a substrate; a first integrated device coupled to the substrate; a second integrated device coupled to the substrate; and a flexible cable coupled to the first integrated device and the second integrated device.

Aspect 15: The package of aspect 14, wherein the flexible cable is coupled to a first back side of the first integrated device and a second back side of the second integrated device.

Aspect 16: The package of aspects 14 through 15, wherein the flexible cable is coupled to the first integrated device through a first plurality of solder interconnects, and wherein the flexible cable is coupled to the second integrated device through a second plurality of solder interconnects.

Aspect 17: The package of aspects 14 through 16, wherein the flexible cable comprises: a plurality of cable interconnects; and at least one cable dielectric layer.

Aspect 18: The package of aspect 17, wherein the plurality of cable interconnects are coupled to a first plurality of pad interconnects of the first integrated device, through a first plurality of solder interconnects, and wherein the plurality of cable interconnects are further coupled to a second plurality of pad interconnects of the second integrated device, through a second plurality of solder interconnects.

Aspect 19: The package of aspect 18, wherein an electrical path between the first integrated device and the second integrated device includes (i) a solder interconnect from the first plurality of solder interconnects, (ii) a cable interconnect from the plurality of cable interconnects, and/or (iii) a solder interconnect from the second plurality of solder interconnects.

Aspect 20: The package of aspects 14 through 19, further comprising a heat sink coupled to a back side of the first integrated device.

Aspect 21: The package of aspects 14 through 20, wherein the package is implemented in a device that is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 22: The package of aspects 1 through 13, wherein the package is implemented in a device that is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a substrate;
a first integrated device coupled to the substrate;
a second integrated device coupled to the substrate; and
a plurality of wire bonds coupled to the first integrated device and the second integrated device.

2. The package of claim 1, wherein the plurality of wire bonds are coupled to a first back side of the first integrated device and a second back side of the second integrated device.

3. The package of claim 1,
wherein the plurality of wire bonds comprise a first plurality of wire bonds and a second plurality of wire bonds,
wherein the first plurality of wire bonds comprise a first plurality of ball bonds and a first plurality of wedge bonds,
wherein the first plurality of ball bonds are coupled to the first integrated device,
wherein the first plurality of wedge bonds are coupled to the second integrated device,
wherein the second plurality of wire bonds comprise a second plurality of ball bonds and a second plurality of wedge bonds,
wherein the second plurality of ball bonds are coupled to the second integrated device, and
wherein the second plurality of wedge bonds are coupled to the first integrated device.

4. The package of claim 3, wherein the first plurality of wire bonds and the second plurality of wire bonds are arranged such that wire bonds alternate between a wire bond from the first plurality of wire bonds and a wire bond from the second plurality of wire bonds.

5. The package of claim 3,
wherein the first integrated device comprises a first row of first pad interconnects and a second row of first pad interconnects,
wherein the second integrated comprises a first row of second pad interconnects and a second row of second pad interconnects,
wherein the first plurality of ball bonds are coupled to the first row of first pad interconnects of the first integrated device,
wherein the first plurality of wedge bonds are coupled to the second row of second pad interconnects of the second integrated device,
wherein the second plurality of ball bonds are coupled to the first row of second pad interconnects of the second integrated device, and
wherein the second plurality of wedge bonds are coupled to the second row of first pad interconnects of the first integrated device.

6. The package of claim 1, wherein a first electrical path between the first integrated device and the second integrated device includes a wire bond from the plurality of wire bonds.

7. The package of claim 6, wherein a second electrical path between the first integrated device and the second integrated device includes at least one interconnect from the substrate.

8. The package of claim 1, further comprising a heat sink coupled to a back side of the first integrated device.

9. The package of claim 8, wherein the heat sink is coupled to the back side of the first integrated device through an adhesive.

10. The package of claim 8, wherein the heat sink comprise copper (Cu) and/or silicon (Si).

11. The package of claim 1,
wherein the first integrated device is coupled to the substrate through a first plurality of pillar interconnects and a first plurality of solder interconnects, and
wherein the second integrated device is coupled to the substrate through a second plurality of pillar interconnects and a second plurality of solder interconnects.

12. The package of claim 11,
wherein a first electrical path between the first integrated device and the second integrated device includes a wire bond from the plurality of wire bonds, and
wherein a second electrical path between the first integrated device and the second integrated device includes (i) a pillar interconnect from the first plurality of pillar interconnects, (ii) a solder interconnect from the first plurality of solder interconnects, (iii) at least one interconnect from the substrate, (iv) a solder interconnect from the second plurality of solder interconnects, and/or (v) a pillar interconnect from the second plurality of pillar interconnects.

13. The package of claim 1, wherein the first integrated device includes a first thickness and the second integrated device includes a second thickness that is different from the first thickness.

14. A package comprising:
a substrate;
a first integrated device coupled to the substrate;
a second integrated device coupled to the substrate; and
a flexible cable coupled to the first integrated device and the second integrated device.

15. The package of claim 14, wherein the flexible cable is coupled to a first back side of the first integrated device and a second back side of the second integrated device.

16. The package of claim 14,
wherein the flexible cable is coupled to the first integrated device through a first plurality of solder interconnects, and
wherein the flexible cable is coupled to the second integrated device through a second plurality of solder interconnects.

17. The package of claim 14, wherein the flexible cable comprises:
a plurality of cable interconnects; and
at least one cable dielectric layer.

18. The package of claim 17,
wherein the plurality of cable interconnects are coupled to a first plurality of pad interconnects of the first integrated device, through a first plurality of solder interconnects, and
wherein the plurality of cable interconnects are further coupled to a second plurality of pad interconnects of the second integrated device, through a second plurality of solder interconnects.

19. The package of claim 18, wherein an electrical path between the first integrated device and the second integrated device includes (i) a solder interconnect from the first plurality of solder interconnects, (ii) a cable interconnect from the plurality of cable interconnects, and/or (iii) a solder interconnect from the second plurality of solder interconnects.

20. The package of claim 14, further comprising a heat sink coupled to a back side of the first integrated device.
